(19) United States
(12) Patent Application Publication
(10) Pub. No.: US 2020/0313076 A1
(43) Pub. Date: Oct. 1, 2020

(54) SPIN ORBIT MEMORY DEVICES WITH ENHANCED TUNNELING MAGNETORESISTANCE RATIO (TMR) AND METHODS OF FABRICATION

(71) Applicant: Intel Corporation, Santa Clara, CA (US)

(72) Inventors: Kaan OGUZ, Portland, OR (US); Christopher WIEGAND, Portland, OR (US); Noriyuki SATO, Hillsboro, OR (US); Angeline SMITH, Hillsboro, OR (US); Tanay GOSAVI, Hillsboro, OR (US)

(73) Assignee: Intel Corporation, Santa Clara, CA (US)

(21) Appl. No.: 16/367,131

(22) Filed: Mar. 27, 2019

(51) Int. Cl. H01L 43/02; H01L 43/10; H01F 10/32; H01L 27/22; G11C 11/16; H01L 43/12

(52) U.S. Cl. CPC H01L 43/02; H01L 43/10; H01F 10/3272; H01F 10/329; H01F 10/3286; G11C 11/161; H01F 10/3254; H01L 43/12; H01L 27/228

(57) ABSTRACT

A spin orbit memory device includes a first electrode including a beta-phase material. The spin orbit memory device further includes a material layer stack on a portion of the first electrode. The material layer stack includes a first layer on the first electrode, where the first layer includes a bcc material such as molybdenum. The material layer stack further includes layers of a perpendicular magnetic tunnel junction (pMTJ) device on the first layer. The pMTJ device includes a free magnet structure on the first layer, where the free magnet structure includes a first magnet and a second magnet on the first magnet. The pMTJ device further includes a fixed magnet above the free magnet structure and a tunnel barrier layer between the magnet structure and the third magnet and a second electrode coupled with the second magnet.

### BACKGROUND

For the past several decades, the scaling of features in integrated circuits has been a driving force behind an ever-growing semiconductor industry. Scaling to smaller and smaller features enables increased densities of functional units on limited real estate of semiconductor chips. For example, shrinking transistor size allows for the incorporation of an increased number of memory devices on a chip, lending to the fabrication of products with increased functionality. The drive for ever-more functionality, however, is not without issue. It has become increasingly significant to rely on innovative devices such as spin orbit memory devices including a spin orbit electrode coupled with a compatible Magnetic Tunnel Junction (MTJ) device to overcome the requirements imposed by scaling.

Non-volatile embedded memory with spin orbit memory devices, e.g., on-chip embedded memory with non-volatility can enable energy and computational efficiency. However, the technical challenges of assembling a material layer stack to form functional spin orbit memory devices present formidable roadblocks to commercialization of this technology today. Specifically, increasing tunneling magnetoresistance ratio in a spin orbit memory device is an important area of device development.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1A illustrates a cross-sectional view of a spin orbit memory device including a layer between a spin orbit electrode and a magnetic tunnel junction (MTJ) device, in accordance with an embodiment of the present disclosure.

FIG. 1B illustrates a cross-sectional view of individual layers of a ferromagnet structure that is part of a synthetic antiferromagnetic (SAF) structure, in accordance with an embodiment of the present disclosure.

FIG. 1C illustrates a cross-sectional view of a coupling structure including a multilayer stack, in accordance with an embodiment of the present disclosure.

FIG. 1D illustrates a cross-sectional view of alternating magnetic and non-magnetic layers in a coupling structure, in accordance with an embodiment of the present disclosure.

FIG. 1E illustrates a plan view of an MTJ device on a spin orbit electrode, in accordance with an embodiment of the present disclosure.

FIG. 1F illustrates a plan view of a magnetic tunnel junction (MTJ) device having a center that is misaligned from an axis of a spin orbit electrode, in accordance with an embodiment of the present disclosure.

FIG. 2 illustrates a cross-sectional view of a spin orbit memory device having a multilayer stack between a spin orbit electrode and a magnetic tunnel junction device, in accordance with an embodiment of the present disclosure.

FIG. 3A illustrates a spin orbit memory device in a low resistance state.

FIG. 3B illustrates a spin orbit memory device switched to a high resistance state after the application of a spin Hall current.

FIG. 3C illustrates a spin orbit memory device switched to a low resistance state after the application of a spin Hall current.

FIG. 4 illustrates a flow diagram for a method to fabricate a spin orbit memory device, in accordance with embodiments of the present disclosure.

FIG. 5A illustrates a cross-sectional view following the formation of an electrode layer including a spin orbit material above a pair of conductive interconnects, in accordance with embodiments of the present disclosure.

FIG. 5B illustrates a cross-sectional view of the structure in FIG. 5A following formation of an electrode layer on the pair of conductive interconnects and a conductive layer above the electrode layer.

FIG. 5C illustrates a cross-sectional view of the structure in FIG. 5B following the formation of a material layer stack for a magnetic tunnel junction device on the conductive layer.

FIG. 5D illustrates a cross-sectional view of the structure in FIG. 5C following the process of etching the material layer stack to form a magnetic tunnel junction device and following the process of etching the conductive layer to expose the electrode layer.

FIG. 5E illustrates a cross-sectional view of the structure in FIG. 5D following the deposition of a first dielectric material on the MTJ device and planarization of the first dielectric material, followed by the formation of a mask.

FIG. 6A illustrates a cross-sectional view of the structure in FIG. 5E following the process of etching the first dielectric material exposed by the mask and following etching of the electrode layer to form a spin orbit electrode.

FIG. 6B illustrates a plan view of a portion of the structure in FIG. 6A, depicting a plan view shape and size of the magnetic tunnel junction (MTJ) device relative to the spin orbit electrode, in accordance with an embodiment of the present disclosure.

FIG. 7 illustrates the structure of FIG. 6A following the formation of a second dielectric material adjacent to the spin orbit electrode and the first dielectric material.

FIG. 8A illustrates a cross sectional view depicting an embodiment where a dielectric spacer is formed adjacent to the MTJ prior to patterning the electrode layer.

FIG. 8B illustrates a plan view depicting an embodiment where a dielectric spacer is formed adjacent to the MTJ.

FIG. 9 illustrates a cross-sectional view of a spin orbit memory device coupled to a transistor.

FIG. 10 illustrates a computing device in accordance with embodiments of the present disclosure.

FIG. 11 illustrates an integrated circuit (IC) structure that includes one or more embodiments of the present disclosure.

### DESCRIPTION OF THE EMBODIMENTS

Spin orbit memory devices with enhanced tunneling magnetoresistance ratio (TMR) and methods of fabrication are described. In the following description, numerous specific details are set forth, such as structural schemes and detailed fabrication methods in order to provide a thorough understanding of embodiments of the present disclosure. It will be apparent to one skilled in the art that embodiments of the present disclosure may be practiced without these specific details. In other instances, well-known features, such as transistor operations and switching operations associated with embedded memory, are described in lesser detail in order to not unnecessarily obscure embodiments of the present disclosure. Furthermore, it is to be understood that the various embodiments shown in the Figures are illustrative representations and are not necessarily drawn to scale.

In some instances, in the following description, well-known methods and devices are shown in block diagram form, rather than in detail, to avoid obscuring the present disclosure. Reference throughout this specification to “an embodiment” or “one embodiment” or “some embodiments” means that a particular feature, structure, function, or characteristic described in connection with the embodiment is included in at least one embodiment of the disclosure. Thus, the appearances of the phrase “in an embodiment” or “in one embodiment” or “some embodiments” in various places throughout this specification are not necessarily referring to the same embodiment of the disclosure. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, magnetic or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example, in the context of materials, one material or material disposed over or under another may be directly in contact or may have one or more intervening materials. Moreover, one material disposed between two materials may be directly in contact with the two layers or may have one or more intervening layers. In contrast, a first material “on” a second material is in direct contact with that second material/material. Similar distinctions are to be made in the context of component assemblies. As used throughout this description, and in the claims, a list of items joined by the term “at least one of” or “one or more of” can mean any combination of the listed terms.

The term “adjacent” here generally refers to a position of a thing being next to (e.g., immediately next to or close to with one or more things between them) or adjoining another thing (e.g., abutting it).

The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

Here, an in-plane magnet refers to a magnet that has magnetization in a direction substantially along the plane of the magnet. For example, a magnet with a magnetization which is in an x or y direction and is in a range of 0 (or 180 degrees)+/−20 degrees relative to an x-y plane of a device.

The term “free” or “unfixed” here with reference to a magnet refers to a magnet whose magnetization direction can change along its easy axis upon application of an external field or force (e.g., Oersted field, spin torque, etc.). Conversely, the term “fixed” or “pinned” here with reference to a magnet refers to a magnet whose magnetization direction is pinned or fixed along an axis and which may not change due to application of an external field (e.g., electrical field, Oersted field, spin torque).

As used throughout this description, and in the claims, a list of items joined by the term “at least one of” or “one or more of” can mean any combination of the listed terms. Unless otherwise specified in the explicit context of their use, the terms “substantially equal,” “about equal” and “approximately equal” mean that there is no more than incidental variation between two things so described. In the art, such variation is typically no more than +/−10% of a predetermined target value.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

A spin orbit memory device may include a magnetic tunnel junction (MTJ) device formed on an electrode including a spin orbit material, herein a spin orbit electrode. The MTJ device functions as a memory device where the resistance of the MTJ device switches between a high resistance state and a low resistance state. The resistance state of an MTJ device is defined by a relative orientation of magnetization between a free magnet and a fixed magnet that are separated by a tunnel barrier. When a magnetization of the free magnet and a magnetization of a fixed magnet have orientations that are in the same direction, the MTJ device is said to be in a low resistance state. Conversely, when the magnetization of the free magnet and a fixed magnet each have orientations that are in opposite direction to each other, the MTJ device is said to be in a high resistance state.

As MTJ devices are scaled, the need for smaller memory elements to fit into a scaled cell size has driven the industry in the direction of perpendicular MTJ (pMTJ). pMTJ based memory devices have a fixed magnet and a free magnet each having a magnetic anisotropy that is perpendicular with respect to a plane of an uppermost surface of the free magnet or an uppermost surface of the spin orbit electrode. Resistance switching is brought about in a pMTJ device by passing a critical amount of spin polarized current through the pMTJ device so as to influence the orientation of the magnetization in the free magnet to align with the magnetization in the fixed magnet. The act of influencing the magnetization is brought about by a phenomenon known as spin torque transfer, where the torque from the spin polarized current is imparted to the magnetization of the free magnet. By changing the direction of the current, the direction of magnetization in the free magnet may be reversed relative to the direction of magnetization in the fixed magnet. Since the free magnet does not need a constant source of spin polarized current to maintain a magnetization direction, the resistance state of the pMTJ device is retained even when there is no current flowing through the pMTJ device. For this reason, the MTJ device belongs to a class of memory devices known as non-volatile memory.

As a pMTJ device is further scaled down in size, the amount of critical spin polarized current density required to switch the device increases. By implementing an MTJ device on a spin orbit electrode, the magnetization in the free magnet can switch direction with an assistance of torque provided by a spin Hall current. The spin Hall current may be induced by passing an electrical current in a transverse direction, through the spin orbit electrode. The spin Hall current arises from spin dependent scattering of electrons due to a phenomenon known as spin orbit interaction. Electrons of one spin polarity are directed towards an upper portion of the spin orbit electrode and electrons with an opposite spin polarity are directed toward a bottom portion of the spin orbit electrode. Electrons of a particular spin polarity are diffused toward the free magnet of the pMTJ device and impart a torque on the magnetization of the free magnet. While there are benefits of spin Hall current assisted switching through implementation of spin orbit electrodes, engineering of perpendicular magnetic tunnel junction devices with high tunnel magnetoresistance (TMR) ratio continues to be challenging.

TMR ratio is a property of a pMTJ that quantifies a ratio of the difference between a high and a low electrical resistance state in a pMTJ to a low resistance state expressed in percent. In general, a TMR ratio number greater than 100% is considered to be high. A high TMR ratio denotes that a pMTJ can achieve a greater electrical resistance difference between a high level and a low level. A large electrical resistance difference enables a large ensemble of pMTJ devices to be operated in a memory array without undergoing erroneous switching. Low erroneous switching is desirable for adequate read/write margins to enable proper device operation. Conversely, a Low TMR ratio may cause read disturb errors. A high TMR ratio allows a greater degree of spin transfer torque for magnetization switching. The TMR ratio depends on the crystallinity of the free magnet and fixed magnet and of the tunnel barrier.

In a spin orbit memory device, a storage magnetic layer (or the free magnet) is closer to the spin orbit electrode than the reference magnetic layer (or fixed layer). In embodiments, where a spin orbit electrode is a lowermost layer of the spin orbit memory device, the crystallinity of the free magnet may be governed by the choice of material of the spin orbit electrode during a fabrication process. In some such embodiments, the spin orbit electrode includes materials such as tantalum and tungsten that have a beta-phase cubic structure. It may be difficult to form a free magnet that has a high degree of body centered cubic (bcc) crystallinity directly on tantalum and tungsten that have a beta-phase cubic structure. The inventors have found that by inserting [1] a thin layer of conductive material having an intrinsic bcc crystal structure between the free magnet and the spin orbit electrode and by [2] engineering a free magnet structure, the free magnet crystallinity may have a high degree of bcc-phase. A measurement of the TMR ratio of a material layer stack for a pMTJ device on a layer of conductive bcc material has shown a TMR value of approximately 140% and an increase in TMR ratio by as much as 15%. An increase in TMR may be indicative of an improvement in the free magnet crystallinity.

The layer of conductive bcc material is designed to have a thickness that does not reduce the spin polarization of the spin current generated in the spin orbit electrode. The conductive bcc material has an electrical resistance that is greater than an electrical resistance of the spin orbit material. A greater electrical resistance enables current to flow in the spin orbit electrode rather than through the conductive layer. Flow of current in the spin orbit electrode is needed to generate spin diffusion current in the spin orbit electrode. In an embodiment, the free magnet structure includes a multi-layer stack including at least two layers of magnetic material. An upper layer may have a lower boron concentration than a lower layer. The upper layer may have a thickness that is at least 0.3 nm thick to maintain perpendicular magnetic anisotropy.

In accordance with embodiments of the present disclosure, a spin orbit memory device includes a first electrode with a beta-phase material. The spin orbit memory device further includes a material layer stack on a portion of the first electrode. The material layer stack includes a first layer on the first electrode, where the first layer includes a body centered cubic (bcc) material such as molybdenum. The material layer stack further includes layers of a magnetic junction device on the first layer. In an embodiment, the magnetic junction device is a magnetic tunnel junction (MTJ) device, such as a perpendicular MTJ (pMTJ) device. The pMTJ device includes a magnet structure on the first layer, where the magnet structure includes a first magnet with a first magnetization and a second magnet with the first magnetization, on the first magnet. The pMTJ device further includes a third magnet (such as a fixed magnet) having a second magnetization, above the magnet structure and a layer including oxygen and a metal between the magnet structure and the third magnet. The magnet structure is a free magnet structure, having a first magnetization that is perpendicular to a plane of an uppermost surface of the free magnet structure. The third magnet is a fixed magnet and has a second magnetization that is also perpendicular. The first magnetization has a direction that may be parallel or anti-parallel to the second magnetization. A second electrode is coupled with the third magnet.

In other embodiments, the spin orbit memory device includes a multi-layer stack with at least three layers that promotes a higher bcc film content in the free magnet structure. The multi-layer stack has a thickness and resistance that may not interfere with current conduction in an underlying spin orbit electrode.

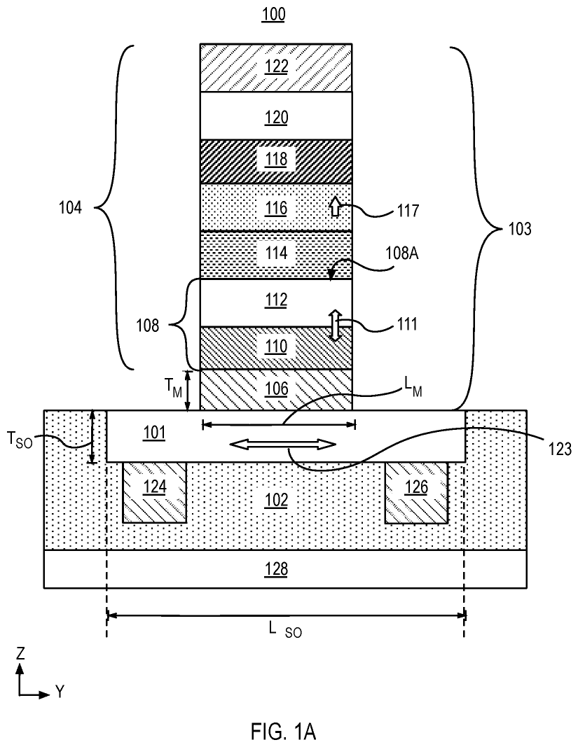

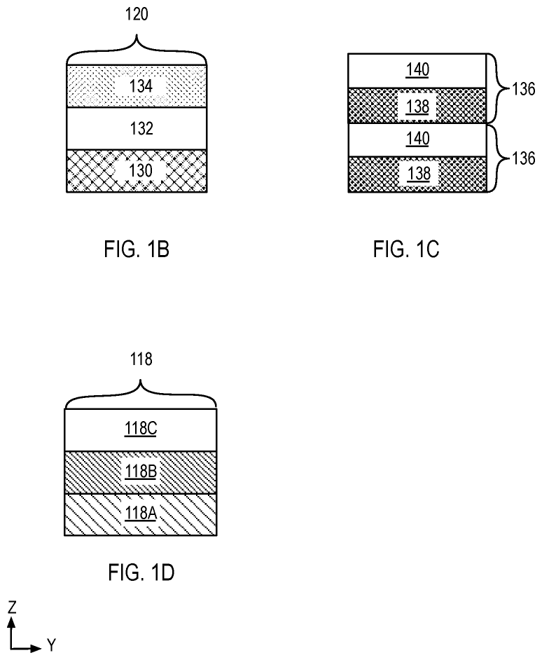

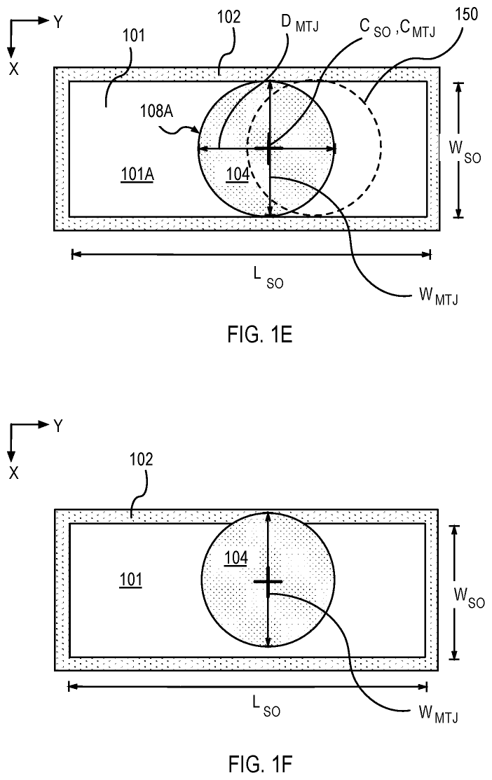

FIG. 1A is an illustration of a cross-sectional view of a spin orbit memory device 100 in accordance with an embodiment of the present disclosure. The spin orbit memory device 100 includes an electrode 101 having a beta-phase material adjacent to a dielectric 102. The electrode 101 is herein referred to as a spin orbit electrode 101. The spin orbit memory device 100 further includes a material layer stack 103 on a portion of the spin orbit electrode 101. The material layer stack 103 further includes a plurality of layers of a magnetic tunnel junction device 104 on a layer 106. The layer 106 includes a conductive material such as molybdenum and is in direct contact with the spin orbit electrode 101.

In an embodiment, the magnetic junction device 104 is a magnetic tunnel junction (MTJ) device 104. In some exemplary embodiments, the MTJ 104 is a perpendicular MTJ (pMTJ) device 104. The pMTJ device 104 includes a magnet structure 108 on the layer 106, where the magnet structure 108 includes a first magnet 110 with a first magnetization 111 and a second magnet 112 with the first magnetization 111 on the first magnet 110. The magnetization 111 may orient in the positive or negative Z-direction (as indicated by the bi-directional arrow) during operation. A magnet structure 108 with magnetization 111 is herein referred to as a free magnet structure 108. The Z axis in FIG. 1A is perpendicular to a plane of an uppermost surface 108A of the free magnet structure 108. The free magnet structure 108 may also be known as a perpendicular free magnet structure 108.

The pMTJ device 104 further includes a third magnet 116 having a second magnetization 117 (denoted by arrow), above the free magnet structure 108. The magnet 116 has a magnetization 117 that is perpendicular to a plane of an uppermost surface 108A of the free magnet structure 108. In the illustrative embodiment, the magnet 116 has a magnetization 117 along a positive Z direction that is fixed. Such a magnet 116 is herein referred to as a fixed magnet 116. The fixed magnet 116 may also be known as a perpendicular fixed magnet 116. The pMTJ device 104 further includes a layer 114 including oxygen and a metal between the free magnet structure 108 and the fixed magnet 116.

The pMTJ device 104 includes a coupling layer 118 above the fixed magnet 116 and a synthetic antiferromagnetic (SAF) structure 120 above the coupling layer 118 to deter accidental flipping of the magnetization 117 in the fixed magnet 116. The coupling layer 118 provides magnetic coupling between fixed magnet 116 and SAF structure 120. The coupling layer 118 also provides a texture breaking interface between the fixed magnet 116 and a lower most layer of the SAF structure 120. Texture breaking is desirable because in many embodiments fixed magnet 116 has a BCC texture (to lattice match with tunnel barrier 114) and a lowermost layer of the SAF structure 120 has an FCC structure. The pMTJ device 104 also includes a top electrode 122 on the SAF structure 120.

To enable transmission of charge current 123 (indicated by a bi-directional arrow) during operation of spin orbit memory device 100, the spin orbit electrode 101 is coupled by a pair of conductive interconnects 124 and 126 in the dielectric 102 above a substrate 128. In the illustrative embodiment, the conductive interconnect 124 is laterally separated from conductive interconnect 126. The pMTJ device 104 is laterally in between, but, on a plane above the conductive interconnects 124 and 126. In other embodiments, the spin orbit memory device 100 may include a single conductive interconnect for example conductive interconnect 124 below the spin orbit electrode 101 and conductive interconnect 126 above the spin orbit electrode 101 (or vice versa). The conductive interconnects 124 and 126 remain laterally separated with the pMTJ 104 in between in all embodiments for a three terminal spin orbit memory device 100. In an embodiment, the conductive interconnects 124 and 126 each include a barrier layer, such as tantalum nitride, and a fill metal, such as copper, tungsten or ruthenium.

In an embodiment, spin orbit electrode 101 includes a material having a high spin Hall efficiency. When a charge current is passed through the spin orbit electrode 101, having a high spin hall efficiency, a large spin Hall current is generated in a direction (Z-axis) transverse to the charge current 123 (Y-axis). A large spin Hall current can provide a spin polarized current to the free magnet structure 108. A spin Hall current induced spin polarized current can provide spin-transfer torque and influence the magnetization of the free magnet structure 108. In an embodiment, the beta phase material is tantalum. In other embodiments the beta phase material is tungsten, or an alloy of tantalum and tungsten. In an embodiment, the spin orbit electrode 101 has a thickness between 5 nm and 20 nm.

While a beta phase material such as tantalum and tungsten can provide high interfacial perpendicular anisotropy to an adjacent free magnet structure 108, the crystallinity of the free magnet structure 108 may be enhanced by the presence of the layer 106. In the illustrative embodiment, the layer 106 includes molybdenum which has a body centered cubic (bcc) crystal structure. Lattice matching a crystal structure of the free magnet structure 108 with a bcc layer 106 enables a higher tunneling magnetoresistance (TMR) ratio in the pMTJ device 104.

Molybdenum has a lower electrical resistivity compared to tantalum and an electrical resistivity that is comparable to tungsten. The molybdenum layer 106 has lateral and vertical dimensions (along Y and Z directions respectively) that are less than lateral and vertical dimensions of the spin orbit electrode 101 to have a greater electrical resistance than spin orbit electrode 101. A greater electrical resistance may force charge current to traverse a path in the spin orbit electrode 101 rather than traverse through the molybdenum layer 106.

In an embodiment the layer 106 has a thickness T_{M} that is less than a thickness, T_{SO}, of the spin orbit electrode 101. In an embodiment, the layer 106 has a thickness between 0.2 nm and 1.0 nm. A thickness between 0.2 nm and 1.0 nm may be sufficiently thin such that the charge current 123 is confined in spin orbit electrode 101 during operation of memory device 100.

In the illustrative embodiment, the layer 106 has a length LM, that is less than a length, L_{SO}, of the spin orbit electrode 101. In one such embodiment, the charge current 123 is confined in spin orbit electrode 101 in regions not covered by the layer 106. In other embodiments, when Lm is less than a length, L_{SO} the charge current 123 is confined in the entire spin orbit electrode 101. In a third embodiment, when LM is less than L_{SO} and T_{M} is less than T_{SO}, the charge current 123 is confined in the entire spin orbit electrode 101, including portions directly under the layer 106, during operation of memory device 100.

In the illustrative embodiment, each of the free magnet 110 includes a magnetic material such as Co, Ni, Fe or alloys of these materials. In an embodiment, the free magnet 110 includes a magnetic material such as CoB, FeB, CoFe or CoFeB. In some embodiments, the free magnet 110 includes a Co_{100-x-y}FeₓB_{y}, where X and Y each represent atomic percent, further where X is between 50 and 80 and Y is between 10 and 40, and further where the sum of X and Y is less than 100. In one specific embodiment, X is 60 and Y is 20. In an embodiment, the free magnet 110 is FeB, where the concentration of boron is between 10 and 40 atomic percent of the total composition of the FeB alloy.

In an embodiment, the free magnet 112 includes a magnetic material such as Co, Ni, Fe or alloys of these materials. In an embodiment, the free magnet 112 includes a magnetic material such as CoB, FeB, CoFe or CoFeB. In some embodiments, the free magnet 112 includes a Co_{100-x-y}FeₓB_{y}, where X and Y each represent atomic percent, further where X is between 50 and 80 and Y is between 10 and 40, and further where the sum of X and Y is less than 100. In one specific embodiment, Xis 60 and Y is 20. In an embodiment, the free magnet 112 is FeB, where the concentration of boron is between 10 and 40 atomic percent of the total composition of the FeB alloy.

In an embodiment, the free magnet 110 and the free magnet 112 each include Co_{100-x-y}FeₓB_{y}, where X and Y each represent atomic percent. In one such embodiment, free magnet 110 has between 30 to 40 atomic percent of boron in Co_{100-x-y}FeₓB_{y} and free magnet 112 has between 20 to 25 atomic percent of boron in Co_{100-x-y}FeₓB_{y}. In embodiments, when the free magnet 110 has between 30 to 40 atomic percent of boron in Co_{100-x-y}FeₓB_{y} and free magnet 112 has between 20 to 25 atomic percent of boron in Co_{100-x-y}FeₓB_{y}, the iron to cobalt ratio is substantially three to one.

In an embodiment, a memory device 100 includes a bcc molybdenum layer 106, and a free magnet 110 including Co_{100-x-y}FeₓB_{y} (where Y is between 30 and 40) that is substantially lattice matched to the bcc molybdenum layer 106. In one such embodiment, free magnet 112 including Co_{100-x-y}FeₓB_{y} (where Y is between 20 and 25) is also substantially lattice matched to the bcc molybdenum layer 106 and to the free magnet 110 including Co_{100-x-y}FeₓB_{y} (where Y is between 30 and 40). Lattice matching a crystal structure of the free magnets 110 and 112 with the bcc molybdenum layer 106 enables a higher tunneling magnetoresistance (TMR) ratio in the pMTJ device 104.

In one embodiment, free magnet 110 has a thickness in the range of 0.2 nm to 1.3 nm and free magnet 112 has a thickness in the range of 0.2 nm to 1.0 nm. In one example, the free magnet structure 108 has a combined total thickness of free magnet 110 and free magnet 112 in the range of 1 nm to 2.0 nm. A thickness of less than 2.0 nm enables perpendicular magnetization in the free magnet structure 108.

In an embodiment, free magnet 112 includes Co_{100-x-y}FeₓB_{y} (where Y is between 20 and 25) and has a thickness in the range of 0.5 nm to 0.7 nm and free magnet 110 includes Co_{100-x-y}FeₓB_{y} (where Y is between 30 and 40) and has a thickness in the range of 0.5 nm to 1.3 nm.

In an embodiment, tunnel barrier (or spin filter layer) 114 includes a material suitable for allowing electron current having a majority spin to pass through tunnel barrier 114, while impeding, at least to some extent, electron current having a minority spin from passing through tunnel barrier 114. Thus, tunnel barrier 114 (or spin filter layer) may also be referred to as a tunneling layer for electron current of a particular spin orientation. In an embodiment, tunnel barrier 114 includes a material such as, but not limited to, oxygen and at least one of magnesium (e.g., a magnesium oxide, or MgO), or aluminum (e.g., an aluminum oxide such as Al₂O₃). In an embodiment, tunnel barrier 114 including MgO has a crystal orientation that is (001) and is lattice matched to free magnet 112 below tunnel barrier 114 and fixed magnet 116 above tunnel barrier 114. In an embodiment, tunnel barrier 114 is MgO and has a thickness in the range of 0.7 nm to 3 nm. In an embodiment, a free magnet 112 including a Co_{100-x-y}FeₓB_{y}, is highly lattice matched to the tunnel barrier 114 including an MgO. Lattice matching between a crystal structure of the free magnet 112 and the tunnel barrier 114 enables a higher tunneling magnetoresistance (TMR) ratio in the pMTJ device 104.

In some embodiments, the fixed magnet 116 includes a material and has a thickness sufficient for maintaining a fixed magnetization. In an embodiment, the fixed magnet 116 of the pMTJ device 104 includes an alloy such as CoFe or CoFeB. In an embodiment, the fixed magnet 116 comprises a Co_{100-x-y}FeₓB_{y}, where X and Y each represent atomic percent, further where X is between 50-80 and Y is between 10 and 40, and further where the sum of X and Y is less than 100. In one specific embodiment, X is 60 and Y is 20. In an embodiment, the fixed magnet 116 is FeB, where the concentration of boron is between 10 and 40 atomic percent of the total composition of the FeB alloy. In an embodiment the fixed magnet 116 has a thickness that is between 0.7 nm and 2 nm.

In an embodiment, the coupling layer 118 includes a metal such as Ta, Ru or Ir. The top electrode 122 includes a material such as Ta or TiN. In an embodiment, the top electrode 122 has a thickness between 5 nm and 70 nm.

In an embodiment, the dielectric 102 includes silicon and at least one of oxygen or nitrogen. In an embodiment, the substrate 128 includes a suitable semiconductor material such as but not limited to, single crystal silicon, polycrystalline silicon and silicon on insulator (SOI). In another embodiment, substrate 128 includes other semiconductor materials such as germanium, silicon germanium or a suitable group III-N or a group III-V compound. Logic devices such as MOSFET transistors and access transistors and may be formed on the substrate 128. Logic devices such as access transistors may be integrated with memory devices such as spin orbit memory device to form embedded memory. Embedded memory including spin orbit memory devices and a logic MOSFET transistors may be combined to form functional integrated circuit such as a system on chip. While the various embodiments here are illustrated with reference to a pMTJ over a spin orbit coupling material, the embodiments are also applicable to spin valves. In an embodiment, a spin valve device includes a layer 114 that is a metal oxide or a metal between the magnet structure 108 and fixed magnet 116 instead of a tunneling dielectric MgO.

FIG. 1B illustrates cross-sectional view of the SAF structure 120 in accordance of an embodiment of the present disclosure. In an embodiment, the SAF structure 120 includes a non-magnetic layer 132 between a pinning ferromagnet 130 and a pinning ferromagnet 134 as depicted in FIG. 1B. The pinning ferromagnet 130 and the second pinning ferromagnet 134 are anti-ferromagnetically coupled to each other. In an embodiment, the pinning ferromagnet 130 includes a layer of a magnetic metal such as Co, Ni, Fe, alloys such as CoFe, CoFeB, or alloys of magnetic metals such as Co, Ni, Fe. In an embodiment, the pinning ferromagnet 134 includes a layer of a magnetic metal comprising Fe, Co or Ni. Exemplary alloys include CoFe or CoFeB. Other magnetic alloys of one or more of Co, Ni, Fe are also possible. In an embodiment, the non-magnetic layer 132 includes a ruthenium or an iridium layer. For example, a ruthenium based non-magnetic layer 132 may have a thickness between 0.3 nm and 1.0 nm to ensure that the coupling between the pinning ferromagnet 130 and the pinning ferromagnet 134 is antiferromagnetic.

In some examples, pinning ferromagnet 130 and 134 each include a stack of bilayers 136 such as is illustrated in FIG. 1C. As shown, the bilayer 136 includes a magnetic layer 138 and a non-magnetic layer 140 on the magnetic layer 138. For illustration purposes, two sets of bilayers 136 are shown. Depending on the desired magnetization, the number of bilayers 136 may range between 2-10 in each pinning ferromagnet 130 and 134. The number of bilayers 136 may be different in each pinning ferromagnet 130 and 134. In an embodiment, the non-magnetic layer 140 includes Pd or Pt and the magnetic layer 138 includes Co. In an embodiment, the multilayer stack of bilayers 136 in pinning ferromagnet 130 is capped by a magnetic layer, where the magnetic layer includes cobalt.

In some embodiments, the non-magnetic coupling layer in may be a coupling structure that includes a multilayer stack. A multilayer stack may be implemented to improve perpendicular magnetic anisotropy in the pMTJ 104 and provide improved coupling between a SAF structure and a fixed magnet.

FIG. 1D illustrates a cross-sectional view of a coupling structure 118 including a multilayer stack, in accordance with an embodiment of the present disclosure. In the illustrative embodiment, the multi-layer stack includes a non-magnetic layer 118A including molybdenum, a magnetic layer 118B on the layer 118A and a non-magnetic layer 118C including Ta, Ru or Ir on the magnetic layer 118B. The magnetic layer 118B may include an alloy of Co, Fe and B such as Co_{100-x-y}FeₓB_{y}, where Y is approximately 30. In an embodiment, the coupling structure 118 has a combined thickness that is less than 2 nm. The non-magnetic layer 118C may have a thickness that is 0.5 nm or less.

A size and shape of the spin orbit electrode 101 may affect the magnitude of a spin Hall current that is generated in the spin orbit electrode 101. In an embodiment, the spin orbit electrode 101 has a rectangular profile as shown in the plan view illustration of FIG. 1E. In some such embodiments, a rectangular top surface 101A has a length, L_{SO}, along the Y-direction. As shown, the pMTJ device 104 has a circular plan view profile. In some such embodiments, a bottom surface 106A of the layer 106 has a diameter, D_{MTJ}. D_{MTJ} may be comparable to LM, in FIG. 1A. Referring again to FIG. 1E, in an embodiment, L_{SO} is at least three times greater than D_{MTJ}. In an embodiment, the spin orbit electrode 101 has a length, L_{SO}, between 50 nm and 500 nm. In an embodiment, D_{MTJ} is between 10 nm and 50 nm. In other embodiments, the pMTJ device 104 has a plan view profile that is rectangular or elliptical.

In the illustrative embodiment, the spin orbit electrode 101 has a width, W_{SO}, along the X-direction in FIG. 1E. In some embodiments, W_{SO}, is between 10 nm and 50 nm. As shown, the pMTJ device 104 has a broadest cross-sectional width, W_{MTJ}, along the direction of the width, W_{SO} of the pMTJ device 104. In an embodiment, W_{MTJ} is the same or substantially the same as W_{SO}. In an embodiment, the pMTJ device 104 has a broadest cross-sectional width, W_{MTJ}, that is between 10 nm and 50 nm. W_{MTJ} may be smaller than W_{SO} in other examples.

In an embodiment, the pMTJ device 104 has a center, C_{MTJ} and the electrode 101 has a center, C_{SO}, as illustrated in the plan view illustration of FIG. 1E. In an embodiment, C_{MTJ} is aligned to C_{SO} in X and Y directions, as illustrated. In another embodiment, CMTJ is misaligned from the C_{SO} in the Y-direction. An example of a pMTJ device 104 that is misaligned is indicated by dashed lines 150. Misalignment may range between 10 nm and 30 nm in X and/or Y directions. The electrical resistivity of the spin orbit electrode 101 may determine a position of the pMTJ device 104 relative to the spin orbit electrode 101 along the Y-direction in FIG. 1E.

When C_{MTJ} is misaligned (along X and/or Y directions) relative to C_{SO}, portions of pMTJ device 104 may extend over a dielectric 102 adjacent to the spin orbit electrode 101. The effect may be more prominent, in some examples, when W_{MTJ} is comparable to W_{SO}, and where C_{MTJ} is misaligned relative to C_{SO} along a Y direction, such as is illustrated in FIG. 1F. Misalignment may occur during a fabrication process and may be indicative of the fabrication process utilized to fabricate a memory device 100.

Referring again to FIG. 1A, while increasing thickness of the molybdenum layer 106 can improve bcc crystallinity, the thickness of the spin orbit electrode 101 will also increase in comparison to maintain a higher resistivity in the molybdenum layer 106. However, as pMTJ devices are scaled, it may be desirable to have a relatively thin molybdenum layer 106, for example a molybdenum layer 106 having a thickness below 2 nm. The spin orbit electrode 101 may have a thickness not exceeding 10 nm to facilitate fabrication (in particular to facilitate patterning). In this context, increasing bcc crystallinity directly competes with thinning of the molybdenum layer 106.

A solution may be availed by adding layers directly above the layer 106 and below the pMTJ device 104. The additional layers can provide alternative pathways to further improve crystallinity of the free magnet structure 108 and increase TMR of the pMTJ device 104. When additional layers that have a bcc crystal structure are added above the molybdenum layer 106, the crystallinity may be improved. However, the overall electrical resistivity may remain comparable or be even higher than a single molybdenum layer 106.

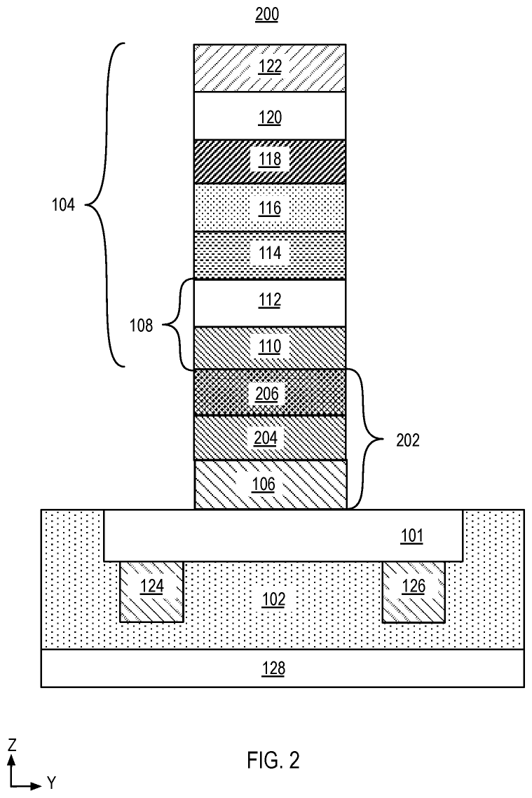

FIG. 2 illustrates a cross-sectional view of a spin orbit memory device 200 having a multilayer stack 202 between spin orbit electrode 101 and magnetic tunnel junction device 104. The multi-layer stack 202 includes a molybdenum layer 106 on the spin orbit electrode 101, a layer 204 including a material having a body centered cubic phase on the layer 106 and a layer 206 including molybdenum on layer 204. The molybdenum in layers 106 and 206 each have a bcc crystal structure. In an embodiment, the layer 204 includes tantalum having a bcc phase. The tantalum in layer 204 is distinguishable from the tantalum in the spin orbit electrode 101 which is a beta-phase material and has high spin Hall coefficient. In contrast to the beta-phase tantalum in the spin orbit electrode 101, bcc tantalum in layer 204 does not have a high spin Hall efficiency.

The multilayer stack 202 has a thickness that is designed to promote bcc crystallinity in the free magnet structure 108 while having a greater electrical resistivity than the spin orbit electrode 101. In an embodiment, the multi-layer stack 202 has a combined thickness between 3 nm and 5 nm.

As discussed above, the molybdenum layer 106 is thinner than the spin orbit electrode 101 and has a thickness that provides greater electrical resistivity. In an embodiment, the molybdenum layer 106 has a thickness between 1 nm and 2 nm. In an embodiment, layer 206 includes tantalum and has a thickness between 1 nm and 4 nm. In an embodiment, layer 106 has a thickness of 1 nm, layer 204 includes bcc tantalum and has a thickness of 1 nm and layer 206 has a thickness of 1 nm. In one such embodiment, the spin orbit electrode 101 has a thickness between 5 nm and 20 nm.

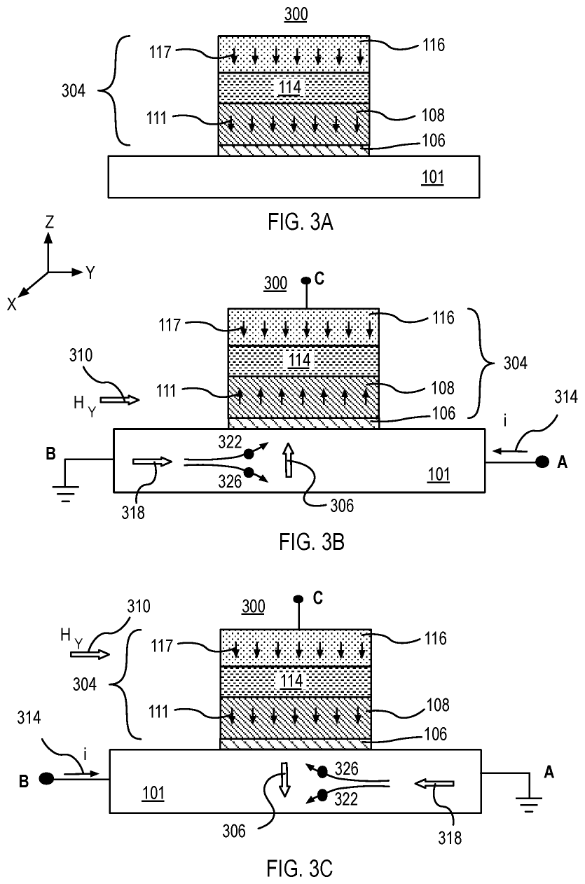

FIGS. 3A-3C illustrate a mechanism for switching a spin orbit memory device such as a spin orbit memory device 300 including a pMTJ device 304 on the electrode 101 including a spin orbit material. In the illustrative embodiment, the pMTJ device 304 includes one or more features of the pMTJ device 104 (FIG. 1A), such as the free magnet structure 108, the fixed magnet 116 and the tunnel barrier 114 between the free magnet structure 108, and the fixed magnet 116.

FIG. 3A illustrates a spin orbit memory device 300 including the pMTJ device 304 on the electrode 101. The pMTJ device 304 includes spin orbit electrode 101, conductive layer 106 on spin orbit electrode 101, free magnet structure 108 on conductive layer 106, tunnel barrier 114 on the free magnet structure 108 and fixed magnet 116 on the tunnel barrier 114. In the illustrative embodiment, magnetization 111 of the free magnet structure 108 is aligned in a direction that is parallel to the magnetization 117 of the fixed magnet 116. In an embodiment, magnetization 111 and magnetization 117 are both directed in the negative Z-direction as illustrated in FIG. 3A. When the magnetization 111 of the free magnet structure 108 is in the same direction as a magnetization 117 of the fixed magnet 116, pMTJ device 304 is in a low resistance state.

FIG. 3B illustrates the pMTJ device 304 of the spin orbit memory device 300 switched to a high resistance state. In an embodiment, a reversal in the direction of magnetization 111 of the free magnet structure 108 in FIG. 3B relative to the direction of magnetization 111 of the free magnet structure 108 in FIG. 3A is brought about by (a) inducing a spin diffusion current 306 in the electrode 101 in the Y-direction, (by applying a positive voltage bias on terminal A with respect to a grounded terminal B), and (b) by an intrinsic magnetic field 310, H_{y}, from an internal or an external source, along the Y axis.

In an embodiment, a charge current 314 is passed through the electrode 101 in the negative y-direction. In response to the charge current 314, an electron current 318 flows in the positive y-direction. The electron current 318 includes electrons with two opposing spin orientations, a type I electron 322, having a spin oriented in the negative x-direction and a type II electron 326 having a spin oriented in the positive X-direction. In an embodiment, electrons in the electron current 318 experience a spin dependent scattering phenomenon in the electrode 101. The spin dependent scattering phenomenon is brought about by a spin-orbit interaction between the nucleus of the atoms in the electrode 101 and the electrons in the electron current 318. The spin dependent scattering phenomenon causes type I electrons 322, whose spins are oriented in the negative x-direction (into the page of FIG. 3B), to be deflected upward towards an uppermost portion of the electrode 101 and type II electrons 326 whose spins are oriented in the positive X-direction to be deflected downward towards a lowermost portion of the electrode 101. The separation between the type I electrons 322 and the type II electrons 326 induces a polarized spin diffusion current 306 in the electrode 101. In an embodiment, the polarized spin diffusion current 306 is directed upwards toward the free magnet structure 108 of the pMTJ device 104, as is depicted in FIG. 3B. The polarized spin diffusion current 306 exerts a spin Hall torque on the magnetization 111 of the free magnet structure 108. In an embodiment, a torque is also exerted on the magnetization 111 of the free magnet structure 108 by an intrinsic or an extrinsic magnetic field, H_{y}, along the Y axis, as illustrated in FIG. 3B. In the illustrative embodiment, the intrinsic or an extrinsic magnetic field, H_{y} 310 provides a torque component (in the positive Z direction) to break symmetry and switch the magnetization 111 of the free magnet structure 108.

In a different embodiment, the torque due to the external magnetic field, H_{y} 310, can be supplemented by a torque from a spin torque transfer mechanism generated by passing a spin polarized current through the pMTJ device 304 by voltage biasing terminal C. Terminal C may be biased relative to terminal B. In one example terminal B may be at some non-zero potential that is lower than a potential of A and C.

FIG. 3C illustrates the pMTJ device 304 of the spin orbit memory device 300 switched to a low resistance state. In an embodiment, a reversal in the direction of magnetization 111 in the free magnet structure 108 in FIG. 3C compared to the direction of magnetization 111 in the free magnet structure 108 in FIG. 3B is brought about by (a) reversal in the direction of the spin diffusion current 306 in the electrode 101 (by applying a positive voltage bias on terminal B with respect to a grounded terminal A), and (b) by an intrinsic or extrinsic magnetic field 310, H_{y}, from magnetization in the spin orbit electrode 101 along the Y axis.

A read operation may be performed by voltage biasing a third terminal C (connected to the fixed magnet 116) with respect to the either terminal and A and B to determine a state of the MTJ device 104. The terminals A or B may be grounded during the read operation (not illustrated).

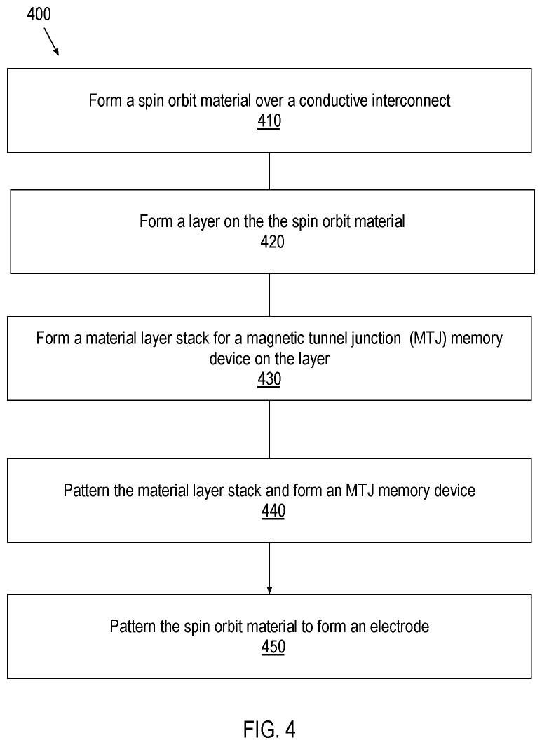

FIG. 4 illustrates a flow diagram of a method to fabricate a spin orbit memory device such as a spin orbit memory device 100. The method 400 begins at operation 410 by forming a spin orbit material on dielectric layer above a substrate. The method 400 continues at operation 420 with the formation of a layer including molybdenum having a bcc crystal structure. The method 400 continues at operation 430 with the deposition of a material layer stack for the formation of an pMTJ device on the layer including molybdenum. In exemplary embodiments, all layers in the material layer stack, the layer including molybdenum and the spin orbit material are blanket deposited in-situ without breaking vacuum. In a simplest embodiment, forming the material layer stack includes a deposition of a free magnetic layer on the layer including molybdenum, deposition of a tunnel barrier layer over the free magnetic layer, deposition of a fixed magnetic layer over the tunnel barrier layer. In an embodiment, the formation of the material layer stack further includes deposition of a plurality of layers of a synthetic antiferromagnetic (SAF) layer over the fixed magnetic layer, and deposition of a conductive material on the SAF layer. The method 400 continues at operation 440 with patterning of the material layer stack to form a pMTJ device and the layer including molybdenum. The method 400 concludes at operation 450 by patterning the spin orbit material to form a spin orbit electrode.

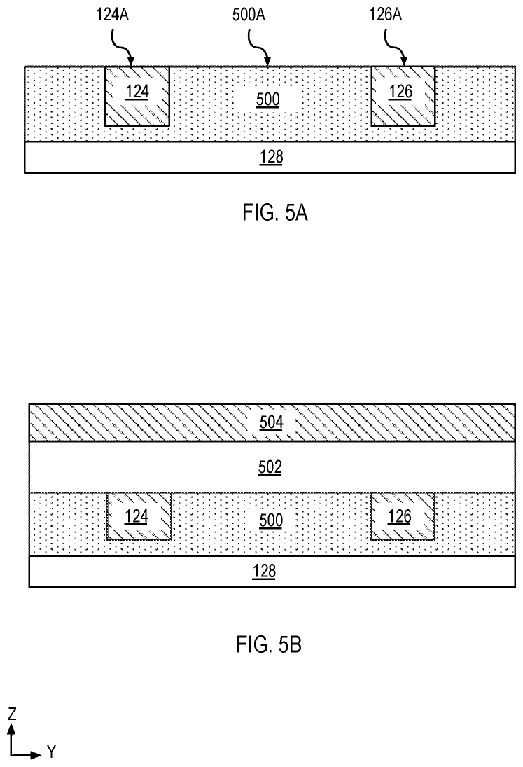

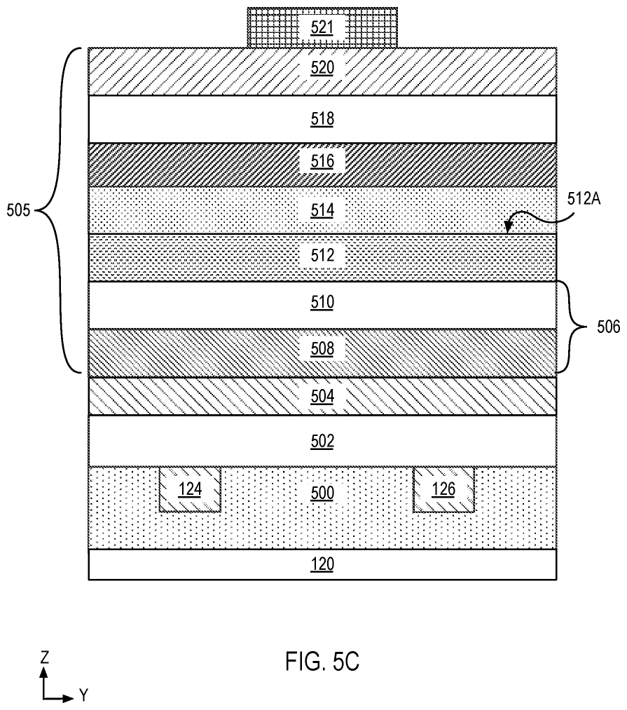

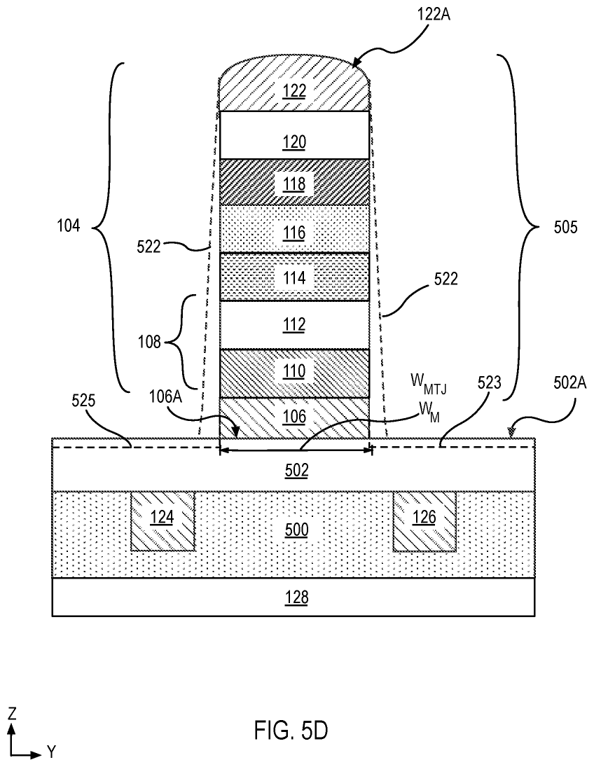

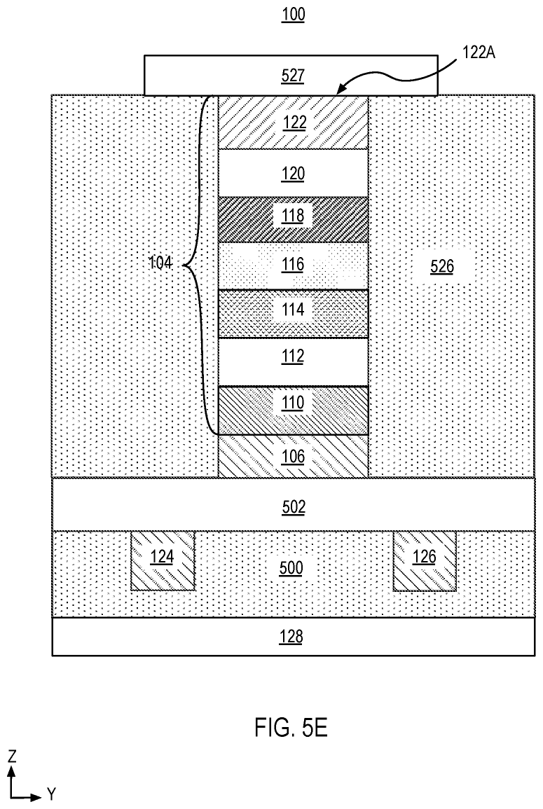

FIG. 5A-FIG. 7 illustrate cross-sectional views of the spin orbit memory device 100 illustrated in FIG. 1A evolving as a fabrication method, such as method 400, is practiced.

FIG. 5A illustrates the structures of conductive interconnects 124 and 126 surrounded by a dielectric material 500 formed above a substrate 128. In an embodiment, the conductive interconnects 124 and 126 are formed in a dielectric material 500 by a damascene or a dual damascene process. In an embodiment, the conductive interconnect 126 includes a barrier layer, such as titanium nitride, ruthenium, tantalum, tantalum nitride, and a fill metal, such as copper, tungsten. In an embodiment, the conductive interconnects 124 and 126 are fabricated using a subtractive etch process when materials other than copper are utilized. In one such embodiment, the conductive interconnects 124 and 126 include a material such as but not limited to titanium nitride, ruthenium, tantalum, tantalum nitride. In some examples, the dielectric material 500 includes a material such as but not limited to silicon dioxide, silicon nitride, silicon carbide, or carbon doped silicon oxide. In an embodiment, the dielectric material 500 has an uppermost surface 500A that is substantially co-planar with each of the uppermost surfaces 124A and 126A of the conductive interconnects 124 and 126, respectively. The dielectric material 500 may include a material that is the same or substantially the same as the dielectric 102 described above. Depending on embodiments, the dielectric material 500 has a total thickness between 70 nm-120 nm. In some examples, at least one of the conductive interconnects 124 or 126 is electrically connected to a circuit element such as an access transistor (not shown). Logic devices such as access transistors may be integrated with memory devices such as a spin orbit device to form embedded memory.

FIG. 5B illustrates a cross-sectional view of the structure in FIG. 5A following the deposition of a layer 502 including a spin orbit material (herein spin orbit layer 502) on the conductive interconnects 124 and 126 and on the dielectric material 500.

In an embodiment, the spin orbit layer 502 is blanket deposited using a physical vapor deposition (PVD) or a chemical vapor deposition (CVD) process. In an embodiment, layer 502 includes a spin orbit material such as tantalum, tungsten or alloys thereof, where the spin orbit material has a beta-phase cubic structure (herein after, spin orbit layer 502). In some embodiments, the spin orbit layer 502 is deposited to a thickness that is between 5 nm and 20 nm. In some embodiments, the as deposited thickness of the spin orbit layer 502 is greater than the final thickness of a spin orbit electrode to be formed as a fraction of the upper portion of the spin orbit layer 502 is removed during the fabrication process.

In an embodiment, the layer 504 is deposited on the spin orbit layer 502 using a PVD process. The layer 504 includes a molybdenum layer. The PVD deposition process utilized enables blanket deposition of a molybdenum layer 504 having a bcc crystal structure. In some examples, the molybdenum layer 504 may be deposited to a thickness between 1 nm and 2 nm. The thickness of the molybdenum layer 504 may be tuned depending on the material and thickness of the spin orbit layer 502, and on lateral dimensions (along X-Y axis) that make up a lateral surface area of a pMTJ device to be formed.

FIG. 5C illustrates a cross-sectional view of the structure in FIG. 5B following the formation of a material layer stack 505 to form a pMTJ device on the layer 504.

In some embodiments, individual layers of a free magnetic structure 506 are sequentially blanket deposited on the layer 504. Deposition of layers of the free magnetic structure 506 includes first depositing a magnetic layer 508 and then depositing magnetic layer 510 on the magnet 508 using a PVD process. The material of magnetic layer 508 and magnetic layer 510 are the same or substantially the same as the material of free magnet 110 and free magnet 112, respectively. In an embodiment, the boron content of the magnetic layer 508 is controlled to deposit a Co_{100-x-y}FeₓB_{y}, where Y is between 30-40 atomic percent and where ratio of Co to Fe is 1 to 3. In one such embodiment, after depositing the magnetic layer 508 to a thickness between 0.5 nm to 1.0 nm, the deposition process is continued to deposit magnetic layer 510 where the boron content in Co_{100-x-y}FeₓB_{y}, is between 20-25 atomic percent. The ratio of Co to Fe is also 1 to 3 in the magnetic layer 510. The magnetic layer 508 is influenced by the bcc crystal structure of the molybdenum.

A tunnel barrier layer 512 is blanket deposited on the magnetic layer 510. In an embodiment, the tunnel barrier layer 512 includes a magnesium and oxygen (for e.g. MgO) or aluminum and oxygen (for e.g. Al₂O₃). In an exemplary embodiment, the tunnel barrier layer 512 is an MgO and is deposited using a reactive sputter process. In an embodiment, the reactive sputter process is carried out at room temperature. In an embodiment, the tunnel barrier layer 512 is deposited to a thickness between 0.5 nm to 2 nm. In an embodiment, the deposition process is carried out in a manner that yields a tunnel barrier layer 512 having an amorphous structure. In some examples, the amorphous tunnel barrier layer 512 becomes crystalline after a high temperature anneal process to be described further below. In other embodiments, the tunnel barrier layer 512 is crystalline as deposited.

In an embodiment, the magnetic layer 514 is blanket deposited on a top surface 512A of the tunnel barrier layer 512. In an embodiment, the deposition process includes a physical vapor deposition (PVD) or a plasma enhanced chemical vapor deposition process. In an embodiment, the PVD deposition process includes an RF or a DC sputtering process. In an exemplary embodiment, the magnetic layer 514 is Co_{100-x-y}FeₓB_{y}, where X and Y each represent atomic percent, further where X is between 50 and 80 and Y is between 10 and 40, and further where the sum of X and Y is less than 100. In some embodiments, the magnetic layer 514 includes a material that is the same or substantially the same as the material of the fixed magnet 116 described above. In some examples, the magnetic layer 514 may be deposited to a thickness between 0.6 nm and 2.0 nm.

The process is continued with deposition of a non-magnetic coupling material 516. In some embodiments, a PVD process is utilized to deposit a single layer of a non-magnetic coupling material 516 such as tantalum ruthenium or iridium. In other embodiments, non-magnetic coupling material 516 includes a multilayer stack such as multilayer stack 118, described in association with FIG. 1F. In some such embodiments, forming the non-magnetic coupling material 516 includes sequentially depositing a layer of molybdenum on the free magnetic layer 514, depositing a magnetic layer such as Co_{100-x-y}FeₓB_{y}, where Y is approximately 30, on the layer of molybdenum, and depositing a layer of tantalum on the magnetic layer.

The process of forming the material layer stack 505 is continued with deposition of layers utilized to form a SAF structure 518. In some embodiments, the layers utilized to form SAF structure 518 are blanket deposited on the non-magnetic coupling material 516 using a PVD process. The layers utilized to form SAF structure 518 are the same or substantially the same as the layers in the SAF structure 120 described above.

In some embodiments, the process utilized to deposit all layers of the material layer stack 505, illustrated in FIG. 5C, is carried without an air break. The individual layers may be blanket deposited using a variety of deposition processes in a cluster tool. Some layers may be deposited using a physical vapor deposition (PVD) process, for example. Other layers, for example, may be deposited by processes that may include a co-sputter or a reactive sputtering process.

In an embodiment, the deposition process concludes with a blanket deposition of a capping layer 520 on an uppermost surface of the layers utilized to form SAF structure 518. The capping layer 520 may act as a hardmask during etching of the pMTJ material layer stack 505. In some examples, the capping layer 520 includes an etch resistant material such as a metal such as Ta or an alloy such as TaN. In an embodiment, the thickness of the capping layer 520 is between 5 nm and 70 nm. The thickness of the capping layer 520 is chosen to accommodate patterning of the pMTJ material layer stack 505 to form a pMTJ device, as well as to act as a top electrode for voltage biasing of the pMTJ device.

In an embodiment, after all the layers in the pMTJ material layer stack 505 are deposited, an anneal is performed. In an embodiment, the anneal is performed post deposition but before formation of a mask 521 on pMTJ material layer stack 505. A post-deposition anneal of the pMTJ material layer stack 505 is carried out in a furnace in vacuum environment. In an embodiment, the anneal temperature ranges between 300 and 450 degrees Celsius.

In an embodiment, the annealing process also promotes solid phase epitaxy of the layers in the free magnetic structure 506. In some embodiments, the magnetic layer 508 follows the bcc crystalline template of the layer 504 below and the magnetic layer 510 follows the bcc crystalline template of the tunnel barrier layer 512 (e.g., MgO) that is directly above the free magnetic structure 506. In an embodiment, the anneal also promotes solid phase epitaxy of the magnetic layer 514 to follow a crystalline template of the tunnel barrier layer 512 (e.g., MgO) that is directly below the magnetic layer 514. <001> Lattice matching between the tunnel barrier layer 512 and the free magnetic structure 506 and <001> lattice matching between the tunnel barrier layer 512 and the magnetic layer 514 enables a TMR ratio of at least 138% to be obtained in the pMTJ material layer stack 505.

In an embodiment, the annealing process is also performed in the presence of a magnetic field which sets a direction of magnetization of the magnetic layer 514 and of the magnet layers 508 and 510. In an embodiment, during the annealing process, an applied magnetic field that is directed perpendicular (along the Z axis) to a horizontal plane (the Y axis) of pMTJ material layer stack 505 enables a perpendicular anisotropy to be set in the magnetic layer 514, in the magnetic layers 508 and 510.

Mask 521 may be formed after formation of the material layer stack 505. In some embodiments, the mask 521 is formed by a lithographic process. In other embodiments, the mask 521 includes a dielectric material that has been patterned. The mask 521 defines a shape and size of a pMTJ device and a location where the pMTJ device is to be subsequently formed with respect the spin orbit electrode 101. In some embodiments, the mask 521 has a circular shape as is depicted in the plan view illustration of FIG. 1E. In the illustrative embodiment, the mask 521 is formed on a plane above, but laterally between the conductive interconnects 124 and 126. The mask 521 may be formed, approximately, midway between conductive interconnects 124 and 126, for example.

FIG. 5D illustrates a cross-sectional view of the structure in FIG. 5C following patterning and etching of the material layer stack 505. In an embodiment, the patterning process first includes etching the capping layer 520 by a plasma etch process to form a top electrode 122. In an embodiment, plasma etch process possesses sufficient ion energy and chemical reactivity to render vertical etched sidewalls of the top electrode 122. In an embodiment, the plasma etch process is then continued to pattern the remaining layers of the material layer stack 505 to form a pMTJ device 104. The plasma etch process etches the various layers in the material layer stack 505 to form an SAF structure 120, a coupling layer 118 (or a coupling structure 118) a fixed magnet 116, a tunnel barrier 114, a free magnet structure 108. The etch process is then continued to also pattern the layer 504 to form layer 106. The layer 504 is removed from portions of the top surface 502A of the spin orbit layer 502 that are not covered by the material layer stack 505. The plasma etch process exposes the spin orbit layer 502. The layer 106 has a same or approximately the same length, WM (along the Y direction) as a width, W_{MTJ} of the free magnet structure 108 after the patterning process.

In some embodiments, depending on the etch parameters, the pMTJ device 104 may have sidewalls that are tapered during the etching process. A taper in sidewalls of pMTJ 104 is indicated by the dashed lines 522.

In other embodiments, depending on the etch selectivity between the material of layer 106 and the material of the spin orbit layer 502, the spin orbit layer surface 502A may be recessed during patterning of the material layer stack 505. For example, spin orbit layer surface 502A may be recessed below the lowermost surface 106A as indicated by the dashed lines 523 and 525. The recess may be between 1 nm-3 nm. The recess across the spin orbit layer 502 may not be uniform. In some such embodiments, the dashed lines 523, 525 may not be at a same level with respect to the spin orbit layer surface 502A.

In the illustrative embodiment, the plasma etch process causes uneven erosion of a top surface 122A of the top electrode 122. A substantially curved top surface 122A may form in some examples, such as in the example illustrated in FIG. 5D.

FIG. 5E illustrates a cross-sectional view of the structure in FIG. 5D following the deposition of a dielectric material on the pMTJ device 104 and planarization of the dielectric 526, followed by the formation of a mask 527 on the pMTJ device 104 and on a portion of the dielectric 526. The dielectric 526 is also formed directly adjacent to the pMTJ 104. In an embodiment, the dielectric material includes a material that is the same or substantially the same as the material of the dielectric material 500. Dielectric 526 may be deposited using a PVD, a CVD or a plasma enhanced CVD process.

A planarization process is carried out, for example, to remove the dielectric 526 above the mask pMTJ 104 and continued until all of the dielectric 526 is removed from above the top electrode 122. The portions of the dielectric 526 remain adjacent to the pMTJ 104 after the planarization process. In an embodiment, the dielectric 526 is further planarized until a portion of the top electrode 122 is removed. After the planarization process, a substantially curved top surface 122A (illustrated in FIG. 5D) may be planarized resulting in a substantially flat top surface 122A (illustrated in FIG. 5E). In an embodiment, the planarization includes a chemical mechanical polish (CMP) process.

In some embodiments, the mask 527 is formed by a lithographic process after the CMP process. In other embodiments, the mask 527 includes a dielectric material that has been patterned. The mask 527 defines a size of an electrode that will subsequently be formed.

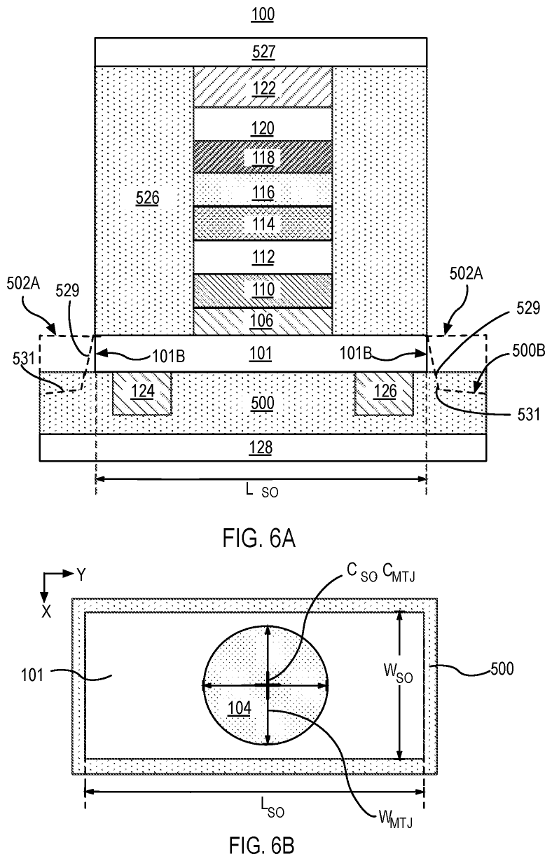

FIG. 6A illustrates a cross-sectional view of the structure in FIG. 5E following the process of etching the dielectric 526 exposed by the mask 527 and following etching of the spin orbit layer surface 502A to form a spin orbit electrode 101.

In an embodiment, a plasma etch process is utilized to first pattern the dielectric 526 and expose the spin orbit layer surface 502A (dashed lines). The patterning processing may be continued to form spin orbit electrode 101. In an embodiment, the spin orbit layer 502 is patterned by a plasma etch process selectively to the mask 527 and the dielectric 526. In other embodiments, the spin orbit layer 502 is patterned by an ion milling process selectively to the mask 527 and the dielectric 526. The ion milling process may be utilized after patterning the dielectric 526.

Depending on the process utilized to form the spin orbit electrode 101, the sidewall 101B of the spin orbit electrode 101 may be vertical in some examples, such as is illustrated. In other examples sidewall 101B may be tapered (as indicated by dashed lines 529). Furthermore, the dielectric material 500 may also be recessed (as indicated by dashed lines 531). Recessed dielectric surface 500B may be non-uniform depending on the patterning process utilized.

The size and shape of the spin orbit electrode 101 depends on the size and shape of mask 527. In the illustrative embodiment, the spin orbit electrode 101 has a length, L_{SO}, that is defined by the mask 527. In some embodiments, the spin orbit electrode 101 has a shape and size as depicted in FIG. 1E.

In other examples, the spin orbit electrode 101 may have dimensions that extend beyond the pMTJ 104 as illustrated in the plan view illustration of FIG. 6B. For example, the width W_{SO}, of the spin orbit electrode 101 may be larger than the width, W_{MTJ}, as shown. The centers C_{MTJ} and C_{SO} may be aligned, also as shown. The mask 527 and the dielectric 526 are not shown in the plan view illustration to clarify a size and location of the pMTJ device 104 relative to the spin orbit electrode 101.

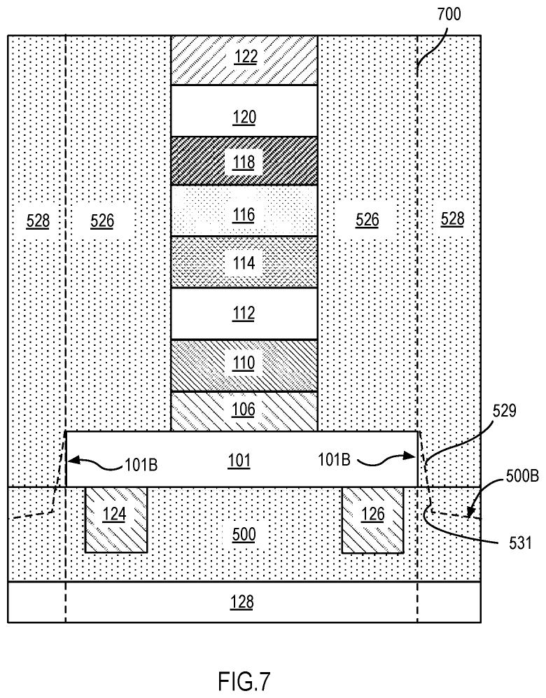

FIG. 7 illustrates the structure of FIG. 6A following the formation of a dielectric material 528 adjacent to sidewalls 101B of the spin orbit electrode 101. In the illustrative embodiment, the dielectric material 528 is also deposited on the dielectric material 500 and adjacent to the dielectric 526 as shown. Dashed lines 700 defines an interface between the dielectric 528 and dielectric 532. In some examples, where dielectric material 500 is recessed (dashed line 531) and the spin orbit electrode 101 has tapered sidewalls 101B (dashed line 529) the dielectric material 528 is adjacent to tapered sidewalls 101B and on a recessed dielectric surface 500B.

The pMTJ device 104 formed over spin orbit electrode 101 and coupled with conductive interconnects 124 and 126 constitutes the perpendicular spin orbit memory device 100, described in association with FIG. 1A.

In an embodiment, a dielectric spacer (inside dashed line 800) is formed adjacent to the pMTJ device after formation of the pMTJ device 104

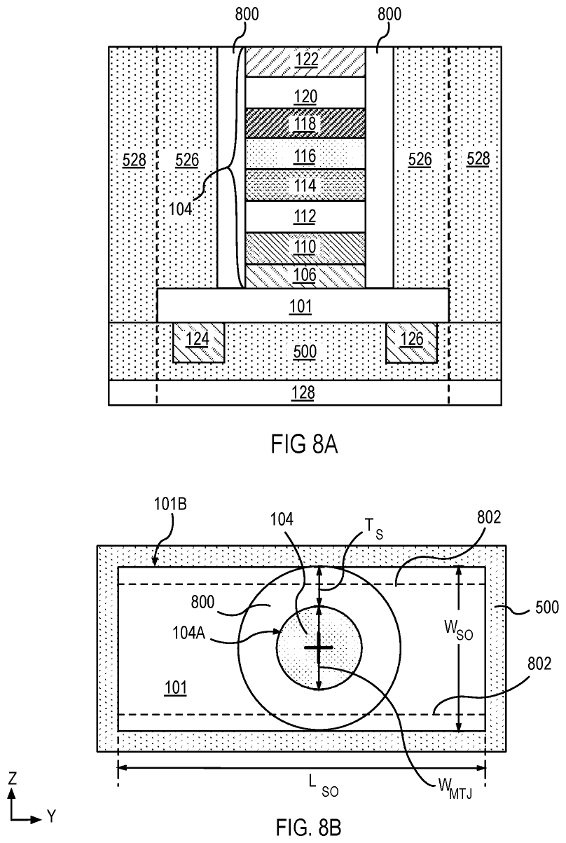

FIG. 8A illustrates a cross-sectional view of a spacer 800 formed adjacent to a pMTJ device 104. In an embodiment, the spacer 800 is formed after patterning of the material layer stack for pMTJ device 104 and forming conductive layer 106. In an embodiment, a dielectric spacer layer is blanket deposited on the structure of FIG. 5D and subsequently patterned. After patterning and forming spacer 800, dielectric 526 is deposited. The process described in association with FIG. 5E-FIG. 7 may be utilized to planarize the dielectric 526 and dielectric 528.

FIG. 8B illustrates a plan view of a dielectric spacer 800 formed adjacent to sidewall 104A of the pMTJ 104. The mask 527 and the dielectric 526 are not shown in the plan view illustration of FIG. 8B to clarify the size and location of the pMTJ device 104 relative to the spin orbit electrode 101. In the illustrative embodiment, the spin orbit electrode 101 has a width, W_{SO}, (along the X-axis) that is equal to a sum of the width, W_{MTJ}, of the pMTJ 104 (along the X-axis) and thickness, Ts, of the dielectric spacer 800 as shown. In other examples (not illustrated), the spin orbit electrode 101 has a width, W_{SO}, (along the X-axis) that is greater than a sum of the width, W_{MTJ}, of the pMTJ 104 (along the X-axis) and thickness, Ts, of the dielectric spacer 800.

In some examples, portions of the dielectric spacer 800 may be removed during formation of the spin orbit electrode 101. In some such examples, a plan view profile of the dielectric spacer 800 and spin orbit electrode 101 may be as indicated by dashed line 802. The dashed lines 802 indicate a boundary of a mask that is utilized to pattern the electrode 101.

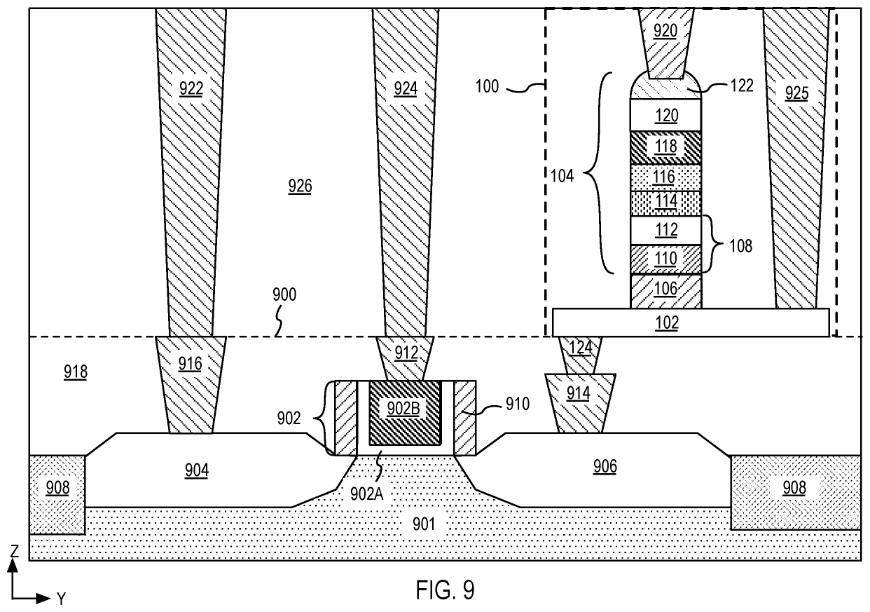

FIG. 9 illustrates a two-terminal spin orbit memory device such as spin orbit memory device 100 coupled to an access transistor 900.

In an embodiment, the transistor 900 is on a substrate 901 and has a gate 902, a source region 904, and a drain region 906. In the illustrative embodiment, an isolation 908 is adjacent to the source region 904, drain region 906 and portions of the substrate 901. In some implementations of the disclosure, such as is shown, a pair of sidewall spacers 910 are on opposing sides of the gate 902.

The transistor 900 further includes a gate contact 912 above and electrically coupled to the gate 902, and a drain contact 914 above and electrically coupled to the drain region 906, and a source contact 916 above and electrically coupled to the source region 904, as is illustrated in FIG. 9. The transistor 900 also includes dielectric 918 adjacent to the gate 902, source region 904, drain region 906, isolation 908, sidewall spacers 910, gate contact 912, drain contact 914 and source contact 916.

In an embodiment, the spin orbit memory device 100 is a perpendicular spin orbit memory device 100 with one or more structural and material properties described above in FIG. 1A. In the illustrative embodiment, the spin orbit memory device 100 includes spin orbit electrode 101, layer 106 on the spin orbit electrode 101 and magnetic tunnel junction (MTJ) device 104 on layer 106. The pMTJ device 104 includes magnet structure 108 where the magnet structure 108 includes a first magnet 110 with a first magnetization and a second magnet 112 with the first magnetization. The pMTJ device 104 further includes magnet 116 having a second magnetization above the magnet structure 108. The pMTJ device 104 further includes a layer 114 including oxygen and a metal between the magnet structure 108 and the magnet 116 and electrode 122 coupled above the fixed magnet 116. In an embodiment, such as is shown the pMTJ device 104 further includes coupling layer 118 above the fixed magnet 116 and SAF structure 120 on the coupling layer 118 and a top electrode 122 on the SAF structure 120.

An MTJ interconnect 920, is coupled with the top electrode 122 as shown. MTJ interconnect 920 may be connected to one or more circuit elements. The spin orbit electrode 101 is above and coupled with conductive interconnect 124 and adjacent to dielectric 918. The pMTJ device 104 is laterally between the conductive interconnect 124 and a spin orbit interconnect 925. The spin orbit interconnect 925 may be connected to a circuit element such as a terminal of an additional transistor.

In the illustrative embodiment, the conductive interconnect 124 is on and above with the drain contact 914. In the illustrative embodiment, one portion of the spin orbit electrode 101 is in electrical contact with a drain contact 914 of transistor 900 through the conductive interconnect 124. In other embodiments, there are one or more additional interconnect structures between drain contact 914 and conductive interconnect 124.

In other embodiments, a perpendicular spin orbit memory device such as perpendicular spin orbit memory device having one or more features of spin orbit memory device 200 may be coupled with the transistor 900.

Gate contact 912 and source contact 916 are each coupled with interconnects. In the illustrative embodiment, gate contact 912 is coupled with a source interconnect 922 and the source contact 916 is coupled with a gate interconnect 924. A dielectric 926 is adjacent to source interconnect 922, gate interconnect 924, memory device 100, source contact 916 and gate contact 912.

In an embodiment, the underlying substrate 901 represents a surface used to manufacture integrated circuits. Suitable substrate 901 includes a material such as single crystal silicon, polycrystalline silicon and silicon on insulator (SOI), as well as substrates 901 formed of other semiconductor materials. In some embodiments, the substrate 901 is the same as or substantially the same as the substrate 128. The substrate 901 may also include semiconductor materials, metals, dielectrics, dopants, and other materials commonly found in semiconductor substrates.

In an embodiment, the transistor 900 associated with substrate 901 are metal-oxide-semiconductor field-effect transistors (MOSFET or simply MOS transistors), fabricated on the substrate 901. In some embodiments, the transistor 900 is an access transistor 900. In various implementations of the disclosure, the transistor 900 may be planar transistors, nonplanar transistors, or a combination of both. Nonplanar transistors include FinFET transistors such as double-gate transistors and tri-gate transistors, and wrap-around or all-around gate transistors such as nanoril6on and nanowire transistors.

In some embodiments, gate 902 includes at least two layers, a gate dielectric layer 902A and a gate electrode 902B. The gate dielectric layer 902A may include one layer or a stack of layers. The one or more layers may include silicon oxide, silicon dioxide (Sift) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer 902A to improve its quality when a high-k material is used.

The gate electrode 902B of the access transistor 900 of substrate 901 is formed on the gate dielectric layer 902A and may consist of at least one P-type work function metal or N-type work function metal, depending on whether the transistor is to be a PMOS or an NMOS transistor. In some implementations, the gate electrode 902B may consist of a stack of two or more metal layers, where one or more metal layers are work function metal layers and at least one metal layer is a conductive fill layer.

For a PMOS transistor, metals that may be used for the gate electrode 902B include, but are not limited to, ruthenium, palladium, platinum, cobalt, nickel, and conductive metal oxides, e.g., ruthenium oxide. A P-type metal layer will enable the formation of a PMOS gate electrode with a work function that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a work function that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode 902B may simply be a planar layer that is substantially parallel to the top surface of the substrate and does not include sidewall portions substantially perpendicular to the top surface of the substrate. In further implementations of the disclosure, the gate electrode may consist of a combination of U-shaped structures and planar, non-U-shaped structures. For example, the gate electrode 902B may consist of one or more U-shaped metal layers formed atop one or more planar, non-U-shaped layers.

The sidewall spacers 910 may be formed from a material such as silicon nitride, silicon oxide, silicon carbide, silicon nitride doped with carbon, and silicon oxynitride. Processes for forming sidewall spacers include deposition and etching process operations. In an alternate implementation, a plurality of spacer pairs may be used, for instance, two pairs, three pairs, or four pairs of sidewall spacers may be formed on opposing sides of the gate stack. As shown, the source region 904 and drain region 906 are formed within the substrate adjacent to the gate stack of each MOS transistor. The source region 904 and drain region 906 are generally formed using either an implantation/diffusion process or an etching/deposition process. In the former process, dopants such as boron, aluminum, antimony, phosphorous, or arsenic may be ion-implanted into the substrate to form the source region 904 and drain region 906. An annealing process that activates the dopants and causes them to diffuse further into the substrate typically follows the ion implantation process. In the latter process, the substrate 901 may first be etched to form recesses at the locations of the source and drain regions. An epitaxial deposition process may then be carried out to fill the recesses with material that is used to fabricate the source region 904 and drain region 906. In some implementations, the source region 904 and drain region 906 may be fabricated using a silicon alloy such as silicon germanium or silicon carbide. In some implementations, the epitaxially deposited silicon alloy may be doped in situ with dopants such as boron, arsenic, or phosphorous. In further embodiments, the source region 904 and drain region 906 may be formed using one or more alternate semiconductor materials such as germanium or a group III-V material or alloy. And in further embodiments, one or more layers of metal and/or metal alloys may be used to form the source region 904 and drain region 906.

In an embodiment, the source contact 916, the drain contact 914 and gate contact 912 each include a multi-layer stack. In an embodiment, the multi-layer stack includes two or more distinct layers of metal such as a layer of Ti, Ru or Al and a conductive cap on the layer of metal. The conductive cap may include a material such as W or Cu.

In an embodiment, the source interconnect 922, gate interconnect 924, spin orbit interconnect 925 and MTJ interconnect 920 includes a material that is the same or substantially the same as the material of the conductive interconnect 124.

The isolation 908 and dielectric 918 and 926 may each include any material that has sufficient dielectric strength to provide electrical isolation. Materials may include silicon and one or more of oxygen, nitrogen or carbon such as silicon dioxide, silicon nitride, silicon oxynitride, carbon doped nitride or carbon doped oxide.

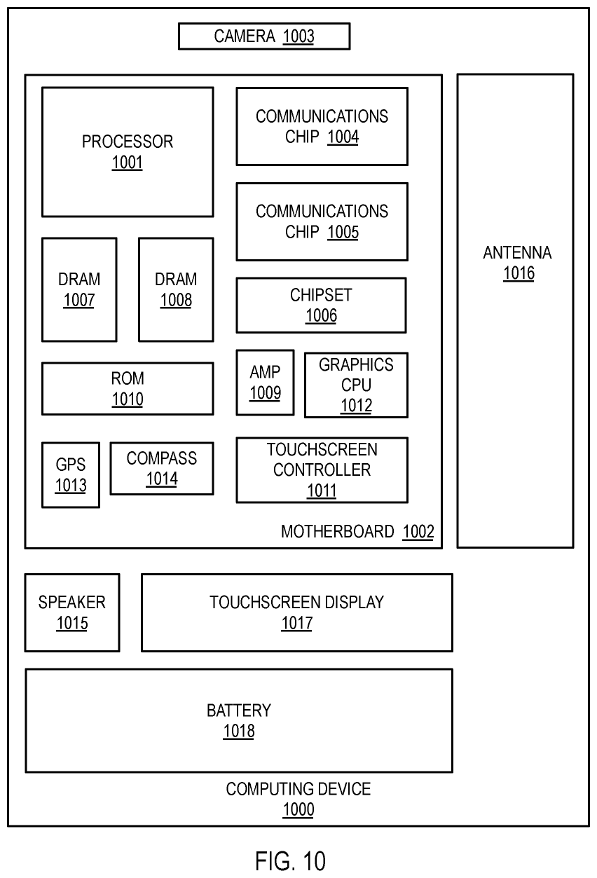

FIG. 10 illustrates a computing device 100 in accordance with embodiments of the present disclosure. As shown, computing device 100 houses a motherboard 1002. Motherboard 1002 may include a number of components, including but not limited to a processor 1001 and at least one communications chip 1004 or 1005. Processor 1001 is physically and electrically coupled to the motherboard 1002. In some implementations, communications chip 1005 is also physically and electrically coupled to motherboard 1002. In further implementations, communications chip 1005 is part of processor 1001.

Depending on its applications, computing device 100 may include other components that may or may not be physically and electrically coupled to motherboard 1002. These other components include, but are not limited to, volatile memory (e.g., DRAM), non-volatile memory (e.g., ROM), flash memory, a graphics processor, a digital signal processor, a crypto processor, a chipset 1006, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communications chip 1005 enables wireless communications for the transfer of data to and from computing device 100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communications chip 1005 may implement any of a number of wireless standards or protocols, including but not limited to Wi-Fi (IEEE 802.11 family), WiMAX (IEEE 802.11 family), long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 100 may include a plurality of communications chips 1004 and 1005. For instance, a first communications chip 1005 may be dedicated to shorter range wireless communications such as Wi-Fi and Bluetooth and a second communications chip 1004 may be dedicated to longer range wireless communications such as GPS, EDGE, GPRS, CDMA, WiMAX, LTE, Ev-DO, and others.

Processor 1001 of the computing device 100 includes an integrated circuit die packaged within processor 1001. In some embodiments, the integrated circuit die of processor 1001 includes one or more transistors, interconnect structures, and non-volatile memory devices such as transistor 900, source interconnect 922, gate interconnect 924, spin orbit interconnect 925, MTJ interconnect 920 and conductive interconnect 124 and memory device 100, respectively. The term “processor” may refer to any device or portion of a device that processes electronic data from registers and/or memory to transform that electronic data into other electronic data that may be stored in registers and/or memory.

Communications chip 1005 also includes an integrated circuit die packaged within communication chip 1005. In another embodiment, the integrated circuit die of communications chips 1004, 1005 includes one or more transistors, interconnect structures, non-volatile memory devices, conductive structures and metallization structures such as transistor 900, source interconnect 922, gate interconnect 924, spin orbit interconnect 925, MTJ interconnect 920 and conductive interconnect 124, and memory device 100, for example. Depending on its applications, computing device 100 may include other components that may or may not be physically and electrically coupled to motherboard 1002. These other components may include, but are not limited to, volatile memory (e.g., DRAM) 1007, 1008, non-volatile memory (e.g., ROM) 1010, a graphics CPU 1012, flash memory, global positioning system (GPS) device 1013, compass 1014, a chipset 1006, an antenna 1016, a power amplifier 1009, a touchscreen controller 1011, a touchscreen display 1017, a speaker 1015, a camera 1003, and a battery 1018, as illustrated, and other components such as a digital signal processor, a crypto processor, an audio codec, a video codec, an accelerometer, a gyroscope, and a mass storage device (such as hard disk drive, solid state drive (SSD), compact disk (CD), digital versatile disk (DVD), and so forth), or the like. In further embodiments, any component housed within computing device 100 and discussed above may contain a stand-alone integrated circuit memory die that includes one or more arrays of NVM devices including one or more memory devices 100 coupled with transistor 900.

In various implementations, the computing device 100 may be a laptop, a netbook, a notebook, an Ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 100 may be any other electronic device that processes data.

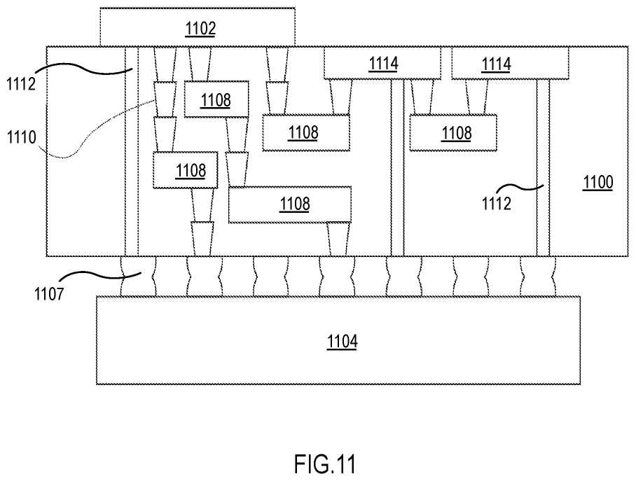

FIG. 11 illustrates an integrated circuit (IC) structure 1100 that includes one or more embodiments of the disclosure. The integrated circuit (IC) structure 1100 is an intervening substrate used to bridge a first substrate 1102 to a second substrate 1104. The first substrate 1102 may be, for instance, an integrated circuit die. The second substrate 1104 may be, for instance, a memory module, a computer mother, or another integrated circuit die. Generally, the purpose of an integrated circuit (IC) structure 1100 is to spread a connection to a wider pitch or to reroute a connection to a different connection. For example, an integrated circuit (IC) structure 1100 may couple an integrated circuit die to a ball grid array (BGA) 1107 that can subsequently be coupled to the second substrate 1104. In some embodiments, the first and second substrates 1102/1104 are attached to opposing sides of the integrated circuit (IC) structure 1100. In other embodiments, the first and second substrates 1102/1104 are attached to the same side of the integrated circuit (IC) structure 1100. And in further embodiments, three or more substrates are interconnected by way of the integrated circuit (IC) structure 1100.

The integrated circuit (IC) structure 1100 may be formed of an epoxy resin, a fiberglass-reinforced epoxy resin, a ceramic material, or a polymer material such as polyimide. In further implementations, the integrated circuit (IC) structure may be formed of alternate rigid or flexible materials that may include the same materials described above for use in a semiconductor substrate, such as silicon, germanium, and other group III-V and group IV materials.

The integrated circuit (IC) structure may include metal interconnects 1108 and vias 1110, including but not limited to through-silicon vias (TSVs) 1112. The integrated circuit (IC) structure 1100 may further include embedded devices 1114, including both passive and active devices. Such embedded devices 1114 include capacitors, decoupling capacitors, resistors, inductors, fuses, diodes, transformers, device structure including transistors, such as transistor 900 (described in FIG. 9) coupled with a with one at least one nonvolatile memory device such as memory device 100 having spin orbit electrode including a beta phase material coupled with a perpendicular magnetic tunnel junction 104, in accordance with an embodiment of the present disclosure. The integrated circuit (IC) structure 1100 may further include embedded devices 1114 such as one or more resistive random-access devices, sensors, and electrostatic discharge (ESD) devices. More complex devices such as radio-frequency (RF) devices, power amplifiers, power management devices, antennas, arrays, sensors, and MEMS devices may also be formed on the integrated circuit (IC) structure 1100. In accordance with embodiments of the present disclosure, apparatuses or processes disclosed herein may be used in the fabrication of integrated circuit (IC) structure 1100.

Accordingly, one or more embodiments of the present disclosure relate generally to the fabrication of embedded microelectronic memory. The microelectronic memory may be non-volatile, wherein the memory can retain stored information even when not powered. One or more embodiments of the present disclosure relate to the fabrication of a spin orbit memory device such as the spin orbit memory device 100 including a spin orbit electrode 101 and a conductive layer 106 including a bcc material such as molybdenum on the spin orbit electrode 101. The spin orbit memory device 100 may be used in an embedded non-volatile memory application.

Thus, embodiments of the present disclosure include spin orbit torque memory devices with enhanced TMR and methods of fabrication.

In a first example, a memory device, includes a first electrode including a beta-phase material and a material layer stack on a portion of the first electrode. The material layer stack includes a first layer on the first electrode, where the first layer includes molybdenum. The material layer stack further includes a magnet structure on the first layer. The magnet structure includes a first magnet with a first magnetization and a second magnet with the first magnetization on the first magnet. The material layer stack further includes a third magnet with a second magnetization, where the third magnet is above the second magnet, a second layer between the magnet structure and the third magnet and a second electrode coupled above the third magnet.

In second examples, for any of the first example, the first layer has a thickness between 0.2 nm and 1.0 nm.

In third examples, for any of the first through second examples, the molybdenum has a body centered cubic structure.

In fourth examples, for any of the first through third examples, the first magnet and the second magnet each include cobalt, iron and boron, and the first magnet includes more boron than the second magnet.

In fifth examples, for any of the first through fourth examples, the first magnet includes between 30 to 40 atomic percent of boron and the second magnet includes between 20 to 25 atomic percent boron.

In sixth examples, for any of the first through fifth examples, the iron to cobalt ratio in each of the first magnet and in the second magnet is substantially three to one.

In seventh examples, for any of the first through sixth examples, the first magnet has a thickness between 0.2 nm and 1.3 nm, the second magnet has a thickness between 0.5 nm and 1.0 nm, and the magnet structure has a combined total thickness between 1 nm and 2.0 nm.

In eighth examples, for any of the first through seventh examples, the first electrode has a thickness between 5 nm and 20 nm.

In ninth examples, for any of the first through eighth examples, the first electrode includes tantalum, tungsten or alloys thereof having a beta-phase cubic structure.

In tenth examples, for any of the first through ninth examples, further includes a multi-layer stack between the second magnet and the second electrode where the multi-layer stack includes a first layer including molybdenum, a second layer including cobalt, iron and boron on the first layer, and a third layer including tantalum on the second layer.

In eleventh examples, for any of the first through tenth examples, further includes a synthetic anti-ferromagnet structure between the multi-layer stack and second electrode. The synthetic anti-ferromagnet (SAF) structure includes a first magnetic structure including a stack of alternating layers of magnetic and non-magnetic materials, where the number of alternating layers of magnetic and non-magnetic materials ranges between 2 and 10. The SAF structure further includes a non-magnetic spacer layer on the first magnetic structure and a second magnetic structure on the non-magnetic spacer layer. The second magnetic structure includes a stack of alternating layers of magnetic and non-magnetic materials where the number of alternating layers of magnetic and non-magnetic materials ranges between 2 and 10.

In twelfth examples, for any of the first through eleventh examples, the first and the second magnetizations are along a same plane of the memory device and where the plane of the memory device is defined by a direction orthogonal to a lowermost surface of the first magnet.

In a thirteenth example, a memory device, includes a first electrode having a beta-phase material and a first material layer stack on a portion of the first electrode. The first material layer stack includes a first layer on the first electrode where the first layer includes molybdenum, a second layer including a material having a body centered cubic phase on the first layer and a third layer including molybdenum on the second layer. The memory device further includes a a second material layer stack for a perpendicular magnetic junction device on the first material layer stack. The second material layer stack includes a magnet structure on the third layer. The magnet structure includes a first magnet with a first magnetization, a second magnet with the first magnetization on the first magnet and a third magnet with a second magnetization, where the third magnet is above the second magnet. The second material layer stack further includes a fourth layer between the magnet structure and the second magnet and a second electrode coupled with the second magnet.

In fourteenth examples, for any of the thirteenth example, the first material layer stack has a thickness between 3 nm and 5 nm.

In fifteenth examples, for any of the thirteenth through fourteenth examples, the first layer has a thickness between 1 nm and 2 nm, where the second layer has a thickness between 1 nm and 4 nm, and where the third layer has a thickness between 1 nm and 2 nm.

In sixteenth examples, for any of the thirteenth through fifteenth examples, the first layer includes molybdenum, the second layer includes tantalum, and the third layer includes molybdenum.

In seventeenth examples, for any of the thirteenth through sixteenth examples, the first magnet and the second magnet each include cobalt, iron and boron, where the first magnet includes more boron than the second magnet.

In eighteenth examples, for any of the thirteenth through seventeenth examples, the first magnet includes between 30 and 40 atomic percent of boron, and the second magnet includes between 20 to 25 atomic percent boron.

In a nineteenth example, a system includes a processor and a radio transceiver coupled to the processor, where the transceiver includes a transistor. The transistor includes a drain contact coupled to a drain, a source contact coupled to a source and a gate contact coupled to a gate. A perpendicular spin orbit memory device is coupled with the drain contact. The perpendicular spin orbit memory device includes a first electrode including beta-phase tantalum and a material layer stack on a portion of the first electrode. The material layer stack includes a first layer on the first electrode where the first layer includes molybdenum, and a magnet structure on the first layer. The magnet structure includes a first magnet with a first magnetization, a second magnet with the first magnetization on the first magnet, a third magnet with a second magnetization, where the third magnet is above the second magnet. The material layer stack further includes a second layer between the magnet structure and the second magnet and a second electrode coupled with the second magnet.

In twentieth examples, for any of the nineteenth example, further includes a battery coupled to power at least one of the processor or memory.

What is claimed is:

1. A memory device, comprising:
a first electrode comprising a beta-phase material; and
a material layer stack on a portion of the first electrode, the material layer stack comprising:
a first layer on the first electrode, wherein the first layer comprises molybdenum;
a magnet structure on the first layer, the magnet structure comprising:
a first magnet with a first magnetization;
a second magnet with the first magnetization on the first magnet;
a third magnet with a second magnetization, the third magnet above the magnet structure;
a second layer between the magnet structure and the third magnet; and
a second electrode coupled above the third magnet.

2. The memory device of claim 1, wherein the first layer has a thickness between 0.2 nm and 1.0 nm.

3. The memory device of claim 1, wherein the molybdenum is body centered cubic structure.

4. The memory device of claim 1, wherein the first magnet and the second magnet each comprise cobalt, iron and boron, and wherein the first magnet comprises more boron than the second magnet.

5. The memory device of claim 4, wherein the first magnet comprises between 30 to 40 atomic percent of boron, and wherein the second magnet comprises between 20 to 25 atomic percent boron.

6. The memory device of claim 5, wherein the iron to cobalt ratio in each of the first magnet and in the second magnet is substantially three to one.

7. The memory device of claim 1, wherein the first magnet has a thickness between 0.2 nm and 1.3 nm and the second magnet has a thickness between 0.5 nm and 1.0 nm, and wherein the magnet structure has a combined total thickness between 1 nm and 2.0 nm.

8. The memory device of claim 1, wherein the first electrode has a thickness between 5 nm and 20 nm.

9. The memory device of claim 1, wherein the first electrode comprises tantalum, tungsten or alloys thereof comprising a beta-phase cubic structure.

10. The memory device of claim 1 further comprises a multi-layer stack between the second magnet and the second electrode, the multi-layer stack comprising:
a first layer comprising molybdenum;
a second layer on the first layer, the second layer comprising cobalt, iron and boron; and
a third layer comprising tantalum on the second layer.

11. The memory device of claim 10, further comprises a synthetic anti-ferromagnet structure between the multi-layer stack and second electrode, the synthetic anti-ferromagnet structure comprising:
a first magnetic structure comprising a multilayer stack of alternating layers of magnetic and non-magnetic materials, wherein the number of alternating layers of magnetic and non-magnetic materials ranges between 2 and 10;
a non-magnetic spacer layer on the first magnetic structure; and
a second magnetic structure on the non-magnetic spacer layer, the second magnetic structure comprising a multilayer stack of alternating layers of magnetic and non-magnetic materials, wherein the number of alternating layers of magnetic and non-magnetic materials ranges between 2 and 10.

12. The memory device of claim 1, wherein the first and the second magnetizations are along a same plane of the memory device and wherein the plane of the memory device is defined by a direction orthogonal to a lowermost surface of the first magnet.

13. A memory device, comprising:
a first electrode comprising a beta-phase material; and
a first material layer stack on a portion of the first electrode, the first material layer stack comprising:
a first layer on the first electrode wherein the first layer comprises molybdenum;
a second layer comprising a material having a body centered cubic phase on the first layer; and
a third layer comprising molybdenum on the second layer; and
a second material layer stack for a perpendicular magnetic junction device on the first material layer stack, the second material layer stack comprising:
a magnet structure on the third layer, the magnet structure comprising:
a first magnet with a first magnetization;
a second magnet with the first magnetization on the first magnet;
a third magnet with a second magnetization, the third magnet above the magnet structure;
a fourth layer between the magnet structure and the second magnet; and
a second electrode coupled with the second magnet.

14. The memory device of claim 13, wherein the first material layer stack has a thickness between 3 nm and 5 nm.

15. The memory device of claim 13, wherein the first layer has a thickness between 1 nm and 2 nm, wherein the second layer has a thickness between 1 nm and 4 nm, and wherein the third layer has a thickness between 1 nm and 2 nm.

16. The memory device of claim 13, wherein the first layer comprises molybdenum, the second layer comprises tantalum and wherein the third layer comprises molybdenum.

17. The memory device of claim 13, wherein the first magnet and the second magnet each comprise cobalt, iron and boron, and wherein the first magnet comprises more boron than the second magnet.

18. The memory device of claim 17, wherein the first magnet comprises between 30 and 40 atomic percent of boron, and wherein the second magnet comprises between 20 to 25 atomic percent boron.

19. A system comprising:
a processor;
a radio transceiver coupled to the processor, wherein the transceiver includes a transistor comprising:
a drain contact coupled to a drain;
a source contact coupled to a source; and
a gate contact coupled to a gate; and
a perpendicular spin orbit memory device coupled with the drain contact, the perpendicular spin orbit memory device comprising:
a first electrode comprising beta-phase tantalum; and
a material layer stack on a portion of the first electrode, the material layer stack comprising:
a first layer on the first electrode wherein the first layer comprises molybdenum;
a magnet structure on the first layer, the magnet structure comprising:
a first magnet with a first magnetization;
a second magnet with the first magnetization on the first magnet;
a third magnet with a second magnetization, the third magnet above the second magnet;
a second layer between the magnet structure and the second magnet; and
a second electrode coupled with the second magnet.

20. The system of claim 19, further comprising a battery coupled to power at least one of the processor or memory.
